(19) United States
(12) Patent Application Publication
(10) Pub. No.: US 2025/0105157 A1
(43) Pub. Date: Mar. 27, 2025

(54) BRIDGE CHIP AND SEMICONDUCTOR INTEGRATED MODULE

(71) Applicant: SUMITOMO ELECTRIC INDUSTRIES, LTD., Osaka (JP)

(72) Inventors: Hiroshi UEMURA, Osaka (JP); Keiji TANAKA, Osaka (JP); Katsumi UESAKA, Osaka (JP); Yoichiro KURITA, Tokyo (JP)

(21) Appl. No.: 18/894,360

(22) Filed: Sep. 24, 2024

(30) Foreign Application Priority Data
Sep. 27, 2023 (JP) 2023-164725

(51) Int. Cl. H01L 23/538; H01L 23/00; H01L 25/16

(52) U.S. Cl. CPC H01L 23/5383; H01L 24/16; H01L 25/162; H01L 25/167; H01L 24/48; H01L 24/73; H01L 2224/16227; H01L 2224/48157; H01L 2224/73207; H01L 2924/1426

(57) ABSTRACT

A bridge chip according to one embodiment includes a substrate having a first surface and a second surface opposite to the first surface; a first resin film having flexibility, and formed on the first surface of the substrate; and a metal film formed on the first resin film. The metal film includes a connecting portion for an electrical connection with an element. The substrate includes a buffer portion penetrating through the substrate between the first surface and the second surface. The connecting portion is disposed inside the buffer portion in a plan view of the substrate.

### CROSS-REFERENCE TO RELATED APPLICATION

This application claims priority from Japanese Patent Application No. 2023-164725, filed on Sep. 27, 2023, the entire subject matter of which is incorporated herein by reference.

### TECHNICAL FIELD

The present disclosure relates to a bridge chip and a semiconductor integrated module.

### BACKGROUND

Japanese Unexamined Patent Publication No. 2018-189699 describes an optical transmitter. The optical transmitter includes a Mach-Zehnder modulator, a driver IC, and a wiring substrate. The wiring substrate connects the Mach-Zehnder modulator and the driver IC to each other through flip-chip mounting. The wiring substrate is a flexible substrate made of silicon dioxide (SiO₂) or resin. In the optical transmitter, an inclination of the wiring substrate with respect to the Mach-Zehnder modulator and the driver IC is within ±3°.

A specification of U.S. Patent Application Publication No. 2015/0180580 describes an optical transmitter including an interconnect bridge assembly including a substrate. The substrate of the interconnect bridge assembly electrically connects a modulator driver and a control IC to each other. The substrate is made of a material having flexibility or elasticity. Accordingly, the substrate absorbs a difference between a height of the modulator driver and a height of the control IC.

### SUMMARY

A bridge chip according to the present disclosure includes a substrate having a first surface and a second surface opposite to the first surface; a first resin film having flexibility, and formed on the first surface of the substrate; and a metal film formed on the first resin film. The metal film includes a connecting portion for an electrical connection with an element. The substrate includes a buffer portion penetrating through the substrate between the first surface and the second surface. The connecting portion is disposed inside the buffer portion in a plan view of the substrate.

### BRIEF DESCRIPTION OF THE DRAWINGS

FIG. 1 is a plan view showing an internal structure of a semiconductor integrated module according to an embodiment.

FIG. 2 is a cross-sectional view of the semiconductor integrated module according to the embodiment.

FIG. 3 is a bottom view showing a bridge chip according to the embodiment.

FIG. 4 is a plan view showing the bridge chip according to the embodiment.

FIG. 5 is a cross-sectional view taken along line A-A of FIG. 4.

FIG. 6 is a cross-sectional view taken along line B-B of FIG. 4.

FIG. 7 is a view showing steps of a method for manufacturing a bridge chip according to an embodiment.

FIG. 8 is a view showing steps of the method for manufacturing a bridge chip according to the embodiment.

FIG. 9 is a view showing steps of a method for manufacturing a semiconductor integrated module according to an embodiment.

FIG. 10 is a view for describing deformation of a buffer portion and a support portion of a substrate of the bridge chip according to the embodiment.

FIG. 11 is a plan view showing an internal structure of a semiconductor integrated module according to a first modification example.

FIG. 12 is a cross-sectional view showing the semiconductor integrated module according to the first modification example.

FIG. 13 is a plan view showing a bridge chip according to a second modification example.

FIG. 14 is a cross-sectional view taken along line C-C of FIG. 13.

FIG. 15 is a cross-sectional view taken along line D-D of FIG. 13.

FIG. 16 is a view showing steps of a method for manufacturing a semiconductor integrated module including the bridge chip according to the second modification example.

FIG. 17 is a plan view showing a bridge chip according to a third modification example.

FIG. 18 is a cross-sectional view taken along line E-E of FIG. 17.

FIG. 19 is a plan view showing a bridge chip according to a fourth modification example.

FIG. 20 is a cross-sectional view showing a semiconductor integrated module according to a fifth modification example.

FIG. 21 is a cross-sectional view showing a semiconductor integrated module according to a sixth modification example.

FIG. 22 is a view showing steps of a method for manufacturing a bridge chip according to a seventh modification example.

FIG. 23 is a view showing steps of the method for manufacturing a bridge chip according to the seventh modification example.

FIG. 24 is a view showing steps of a method for manufacturing a bridge chip according to an eighth modification example.

FIG. 25 is a view showing steps of the method for manufacturing a bridge chip according to the eighth modification example.

### DETAILED DESCRIPTION

For example, a plurality of elements such as a driver IC and an optical circuit element may be subjected to the influence of stress caused by expansion or contraction due to a change in temperature in a state where the plurality of elements are accommodated in a housing. Therefore, protection of the elements from the influence of stress and enabling signal transmission between the plurality of elements are required.

An object of the present disclosure is to provide a bridge chip and a semiconductor integrated module capable of improving the robustness of electrical connections between a plurality of elements.

According to the present disclosure, it is possible to improve the robustness of electrical connections between a plurality of elements.

### Description of Embodiment of Present Disclosure

First, contents of an embodiment of a bridge chip and a semiconductor integrated module according to the present disclosure will be listed and described. (1) The bridge chip according to one embodiment includes a substrate having a first surface and a second surface opposite to the first surface; a first resin film having flexibility, and formed on the first surface of the substrate; and a metal film formed on the first resin film. The metal film includes a connecting portion for an electrical connection with an element. The substrate includes a buffer portion penetrating through the substrate between the first surface and the second surface. The connecting portion is disposed inside the buffer portion in a plan view of the substrate.

In the bridge chip, the first resin film having flexibility is formed between the substrate and the metal film. The metal film includes the connecting portion for an electrical connection with the element. The substrate includes the buffer portion penetrating through the substrate, and the connecting portion is disposed inside the buffer portion in a plan view of the substrate. Therefore, the connecting portion, the first resin film having flexibility, and the buffer portion are aligned in order along a lamination direction of the substrate, the first resin film, and the metal film. A portion where the connecting portion is located in a plan view of the substrate is a portion that deforms more easily than other portions since the buffer portion is located below the connecting portion. Therefore, since the connecting portion that is electrically connected to the element is more easily displaced than other portions, even when a change in temperature or the like occurs, a portion of the first resin film which is aligned with the connecting portion along the lamination direction deforms, so that the influence of stress on the element can be reduced. Therefore, the element can be protected from the influence of stress, and robustness between a plurality of elements can be improved.

(2) In the above (1), the bridge chip may further include a second resin film having flexibility, and the second resin film may be formed on the first resin film and the metal film, and may have an opening on the metal film. In this case, a part of the first resin film and a part of the metal film can be covered with the second resin film having flexibility.

(3) In the above (1) or (2), the substrate may further include a support portion inside the buffer portion in a plan view of the substrate.

The connecting portion may be connected to the second surface of the substrate via the first resin film and the support portion. In this case, the connecting portion, the first resin film having flexibility, and the support portion are aligned in order along the lamination direction of the substrate, the first resin film, and the metal film. Therefore, the first resin film and the connecting portion can be supported by the support portion while the portion of the first resin film which is aligned with the connecting portion along the lamination direction is deformed.

(4) In any of the above (1) to (3), the bridge chip may further include a solder bump formed on the connecting portion. In this case, since the solder bump can be melted by heating to connect the connecting portion to the element, the connection of the connecting portion to the element can be easily performed without strongly pressing the connecting portion against the element during connection.

(5) In any of the above (1) to (4), the first resin film may be made of polyimide. In this case, the first resin film can be a resin film having excellent flexibility and stretchability.

(6) In any of the above (1) to (5), the metal film may be made of any of copper, gold, and aluminum.

(7) In any of the above (1) to (6), the metal film may include a wiring that includes a first pad formed as the connecting portion at a first end portion, and a second pad formed as the connecting portion at a second end portion. The first pad may be configured to be electrically connectable to a first element, and the second pad may be configured to be electrically connectable to a second element isolated from the first element. In this case, the first pad of a wiring of the metal film can be electrically connected to the first element, and the second pad of a wiring of the metal film can be electrically connected to the second element.

(8) In any of the above (1) to (6), the metal film may include a plurality of wirings, each extending in a first direction, and each of the plurality of wirings may include a first pad at a first end portion and a second pad at a second end portion. The first pads of the plurality of wirings may be disposed along a second direction intersecting the first direction, and the second pads of the plurality of wirings may be disposed along the second direction. The buffer portion may include a first buffer portion including a plurality of the first pads inside the first buffer portion in a plan view of the substrate, and a second buffer portion including a plurality of the second pads inside the second buffer portion in a plan view of the substrate. In this case, portions of the first resin film which are aligned with the first pads and the second pads in the lamination direction can be made to be more easily deformed than other portions.

(9) In any of the above (1) to (8), the substrate may be made of silicon. In this case, the heating of the substrate can be easily performed during mounting or the like.

(10) In any of the above (1) to (8), the substrate may be made of glass. In this case, thermal insulation of the substrate can be further improved.

(11) In any of the above (1) to (8), the support portion of the substrate may be made of silicon.

(12) A semiconductor integrated module according to one embodiment includes a base having a reference surface; a first element that is mounted on the reference surface, and that transmits an electrical signal; a second element that is mounted on the reference surface, and that receives the electrical signal; and the bridge chip described above that is connected to the first element and the second element, and that transmits the electrical signal. Since the semiconductor integrated module includes the bridge chip described above, the same effects as those described above can be obtained. Namely, since the connecting portion that is electrically connected to each of the first element and the second element is more easily displaced than other portions, even when a change in temperature or the like occurs, a portion of the first resin film which is aligned with the connecting portion along a lamination direction deforms, so that the influence of stress on the first element and the second element can be reduced. Therefore, the first element and the second element can be protected from the influence of stress, and robustness between a plurality of elements can be improved.

### Details of Embodiments of Present Disclosure

Various examples of bridge chips and semiconductor integrated modules according to embodiments will be described below with reference to the drawings. It is intended that the present invention is not limited to the following examples and includes all changes set forth in the claims and within the scope of equivalents to the claims. In the description of the drawings, the same or corresponding elements are denoted by the same reference signs, and duplicate descriptions will be omitted as appropriate. The drawings may be partially depicted in a simplified or exaggerated manner for ease of understanding, and dimensional ratios and the like are not limited to those shown in the drawings. Namely, the dimensions on the drawings may differ from the actual dimensions.

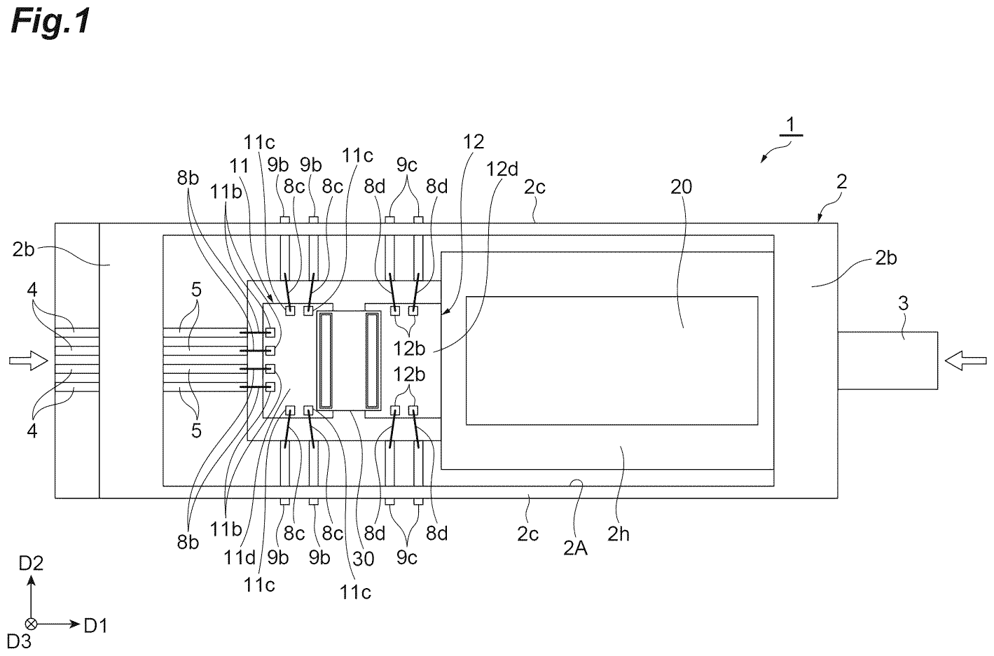

FIG. 1 is a plan view showing an internal structure of a semiconductor integrated module 1 according to the present embodiment.

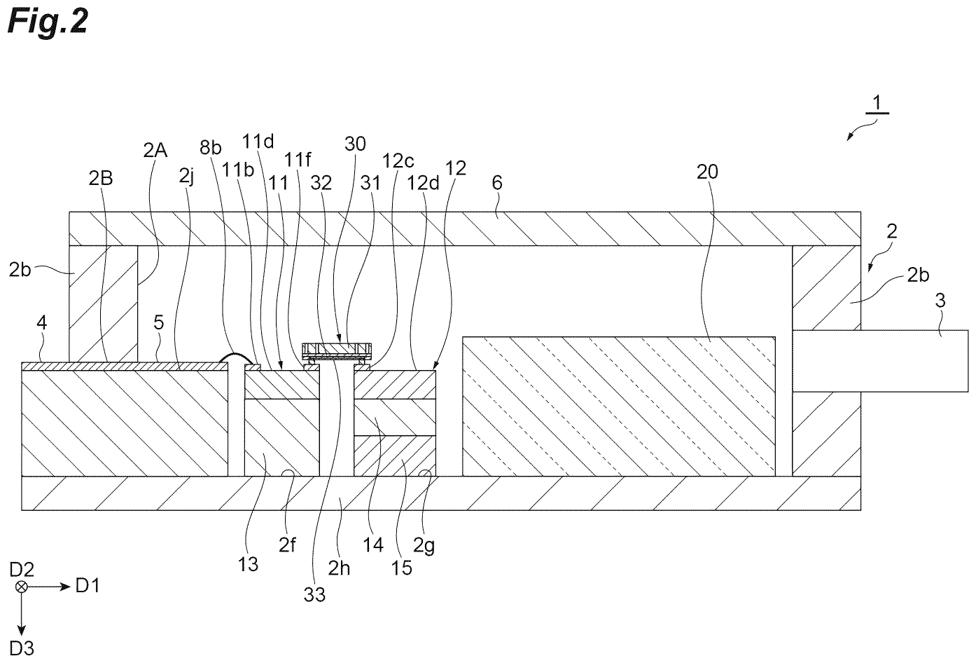

FIG. 2 is a longitudinal sectional view showing the semiconductor integrated module 1. In the present embodiment, the semiconductor integrated module 1 is an optical module. As shown in FIGS. 1 and 2, the semiconductor integrated module 1 is, for example, Transmitter Optical Sub Assembly (TOSA) including a package 2 having a rectangular parallelepiped shape, an optical connector 3, and a terminal 4. The semiconductor integrated module 1 may be, for example, Coherent Driver Module (CDM). The package 2 is made of, for example, ceramic. The package 2 extends in a first direction D1 that is a longitudinal direction of the package 2, a second direction D2 that is a width direction of the package 2, and a third direction D3 that is a height direction of the package 2. For example, the first direction D1, the second direction D2, and the third direction D3 are orthogonal to each other.

The package 2 includes a pair of first side walls 2b located at end portions in the first direction D1; a pair of second side walls 2c located at end portions in the second direction D2; and a bottom wall 2h located at one end in the third direction D3. An internal space 2A of the package 2 is defined by the pair of first side walls 2b, the pair of second side walls 2c, and the bottom wall 2h. Components of the semiconductor integrated module 1 are accommodated in the internal space 2A. The semiconductor integrated module 1 further includes a lid 6 that seals the internal space 2A. The lid 6 is made of, for example, metal. FIG. 1 shows the internal space 2A of the package 2 with the lid 6 omitted in a plan view in the third direction D3.

In the internal space 2A, for example, a driver IC 11 that is a first element, an optical circuit element 12 that is a second element, and an optical component 20 are provided. For example, the optical circuit element 12 is an optical modulator. The driver IC 11 is, for example, such that an electrical circuit is formed on a silicon (Si) substrate using SiGe Bipolar Complementary Metal Oxide Semiconductor (BiCMOS) process, and amplifies an electrical signal supplied from the terminal 4, and supplies the amplified electrical signal to the optical circuit element 12.

The driver IC 11 transmits an electrical signal, and the optical circuit element 12 receives the electrical signal. In the present embodiment, the driver IC 11 supplies an electrical signal to the optical circuit element 12. The optical circuit element 12 is, for example, such that a Mach-Zehnder interferometer is formed on an indium phosphide (InP) substrate, and modulates an optical signal supplied from the outside, based on the electrical signal supplied from the driver IC 11, and outputs the modulated optical signal. A modulation rate of the optical signal is, for example, 200 GBd.

The electrical signal supplied from the driver IC 11 to the optical circuit element 12 passes through, for example, transmission lines formed in an electrical signal output unit of the driver IC 11 and an electrical signal input unit of the optical circuit element 12. These transmission lines may have characteristic impedances substantially equal to each other, and the characteristic impedance is, for example, 60Ω differential. A length of the driver IC 11 in the first direction D1 and a length of the optical circuit element 12 in the first direction D1 are, for example, 2 mm. A length of the driver IC 11 in the second direction D2 and a length of the optical circuit element 12 in the second direction D2 are, for example, 4 mm.

The package 2 includes a heat sink plate (heat sink member). For example, the bottom wall 2h is formed of a heat sink plate. The heat sink plate is made of, for example, copper-tungsten (CuW). The heat sink plate may be made of, for example, a metal material other than CuW. Hereinafter, the bottom wall 2h is also referred to as a heat sink plate. The driver IC 11 is mounted on the heat sink plate (heat sink member) via a heat sink block 13. The heat sink block 13 is bonded to a first surface 2f of the package 2.

The driver IC 11 is bonded to the heat sink block 13 using, for example, a thermally conductive adhesive (not shown) such as silver paste. An alloy solder such as gold-tin (AuSn) solder or tin-silver-copper (SnAgCu) solder may be used instead of the thermally conductive adhesive. The heat sink block 13 is bonded to the first surface 2f of the package 2 using, for example, a thermally conductive adhesive. The heat sink block 13 may be made of, for example, metal or ceramic. In addition, the heat sink block 13 may be made of aluminum nitride.

The optical circuit element 12 is mounted on the bottom wall 2h via, for example, Thermo Electric Cooler (TEC) 15 that is a temperature adjustment element. The TEC 15 is bonded to a second surface 2g of the package 2. For example, the first surface 2f and the second surface 2g are formed on the bottom wall 2h. The second surface 2g is a surface parallel to the first surface 2f. For example, the second surface 2g is located on the same plane as the first surface 2f. A spacer 14 is provided between the optical circuit element 12 and the TEC 15.

The optical circuit element 12 is bonded to the spacer 14 using, for example, a thermally conductive adhesive. The spacer 14 is bonded to the TEC 15 using, for example, a thermally conductive adhesive. The TEC 15 is bonded to the second surface 2g of the package 2 using, for example, a thermally conductive adhesive. The spacer 14 may be provided between the TEC 15 and the bottom wall 2h instead of between the optical circuit element 12 and the TEC 15. A plurality of the spacers 14 may be provided. The spacer 14 may be made of, for example, metal or ceramic. In addition, the spacer 14 may be made of aluminum nitride. For example, an optical component other than the optical circuit element 12 may be mounted on the spacer 14. In addition, the spacer 14 can also be omitted.

For example, the optical component 20 includes at least one of a lens, a mirror, a beam splitter, and an optical filter. The optical component 20 inputs and outputs an optical signal to and from the optical circuit element 12. The optical connector 3 is provided on the first side wall 2b. The optical connector 3 inputs and outputs an optical signal to and from the optical component 20. Regarding direction, a direction in which light is output from the optical connector 3 to the outside of the package 2 may be referred to as the front, the front side, or forward, and a direction opposite to the front, the front side, or forward may be referred to as the rear, the rear side, or rearward. For example, light output from the optical connector 3 to the rear, the rear side, or rearward is input to the optical component 20. However, these directions are defined for convenience of description, and do not limit directions in which the components are disposed.

For example, the package 2 includes electrical wirings 2B. The electrical wirings 2B are, for example, a feed-through electrical wirings that penetrates through the first side wall 2b (rear wall) on the rear side of the package 2 while maintaining the hermeticity (airtightness) of the internal space 2A. Each of the electrical wirings 2B includes two end portions. One end portions (first end portions) of the electrical wirings 2B are exposed to the outside of the package 2. A plurality of the terminals 4 for electrical connections with an external device are disposed to align along the second direction D2 at the end portions of the electrical wirings 2B outside the package 2. The other end portions (second end portions) of the electrical wirings 2B are provided to face the internal space 2A. A plurality of terminals 5 for electrical connections with the driver IC 11 are disposed to align along the second direction D2 at the end portions of the electrical wirings 2B inside the package 2.

The package 2 has a fifth surface 2j on which the electrical wirings 2B are formed, and the terminals 4 and the terminals 5 are further provided on the fifth surface 2j. The terminals 4 and the terminals 5 are electrically connected to each other via the electrical wirings 2B. Therefore, electrical signals can be exchanged between the outside and the inside (internal space 2A) of the package 2 via the electrical wirings 2B. The electrical signals include, for example, a power supply voltage and a ground voltage (ground potential) in addition to an analog signal and a digital signal. The fifth surface 2j is a surface parallel to the first surface 2f.

In the internal space 2A, each of the plurality of terminals 5 is electrically connected to a pad 11b of the driver IC 11 via a bonding wire 8b. The driver IC 11 has a third surface lid on an opposite side from the heat sink block 13, and the pad 11b is provided on the third surface 11d. In addition, a circuit (not shown) of the driver IC 11 is also formed on the third surface 11d. In the package 2, the plurality of terminals 5 are aligned along the second direction D2. In the driver IC 11, a plurality of the pads 11b are aligned along the second direction D2. A plurality of the bonding wires 8b are aligned along the second direction D2, and each of the bonding wires 8b electrically connects the terminal 5 and the pad 11b to each other.

The semiconductor integrated module 1 includes a plurality of terminals 9b and a plurality of terminals 9c extending along the second direction D2 and exposed to the outside of the package 2. One end of each of the terminals 9b and the terminals 9c is exposed to the outside of the package 2 on each of the pair of second side walls 2c. The other end of each of the plurality of terminals 9b is electrically connected to a pad 11c of the driver IC 11 via a bonding wire 8c. The pad 11c is provided on the third surface 11d of the driver IC 11. The terminals 9b and the terminals 9c may be provided only on one of the pair of second side walls 2c.

The other end of each of the plurality of terminals 9c is electrically connected to a pad 12b of the optical circuit element 12 via a bonding wire 8d. The optical circuit element 12 has a fourth surface 12d on an opposite side from the TEC 15, and the pad 12b is provided on the fourth surface 12d of the optical circuit element 12. A circuit (not shown) of the optical circuit element 12 is also formed on the fourth surface 12d. As described above, an electrical signal is supplied to the semiconductor integrated module 1 via at least one of the terminal 4 and the terminals 9b and 9c, and the electrical signal is supplied to the driver IC 11 or the optical circuit element 12 via the bonding wire 8b, 8c, or 8d.

The optical circuit element 12 is formed using, for example, an InP compound semiconductor, and a linear expansion coefficient of the optical circuit element 12 is, for example, 4.5 ppm/° C. The temperature of the optical circuit element 12 is controlled to be constant by the TEC 15. The driver IC 11 is formed on, for example, a Si substrate, and a linear expansion coefficient of the driver IC 11 is, for example, 3 to 4 ppm/° C. The temperature of the driver IC 11 changes depending on the external temperature of the semiconductor integrated module 1, the power consumption of the driver IC 11, and thermal resistance between the heat sink block 13 and the bottom wall 2h. The bottom wall 2h is made of, for example, copper-tungsten (CuW), and has a linear expansion coefficient of 6 to 7 ppm/° C. In such a manner, since the linear expansion coefficients and temperatures of a plurality of the components constituting the semiconductor integrated module 1 are different from each other, the positions of the driver IC 11 and the optical circuit element 12 in the first direction D1, the second direction D2, and the third direction D3 can change depending on the external temperature.

The semiconductor integrated module 1 includes a bridge chip 30 that electrically connects the driver IC 11 and the optical circuit element 12 to each other. Hereinafter, a direction in which the bridge chip 30 is viewed from the driver IC 11 and the optical circuit element 12 may be referred to as the top, upper side or upward, and a direction in which the driver IC 11 and the optical circuit element 12 are viewed from the bridge chip 30 may be referred to as the bottom, lower side or downward. However, these directions are defined for convenience of description, and do not limit the disposition positions, directions, and the like of the components.

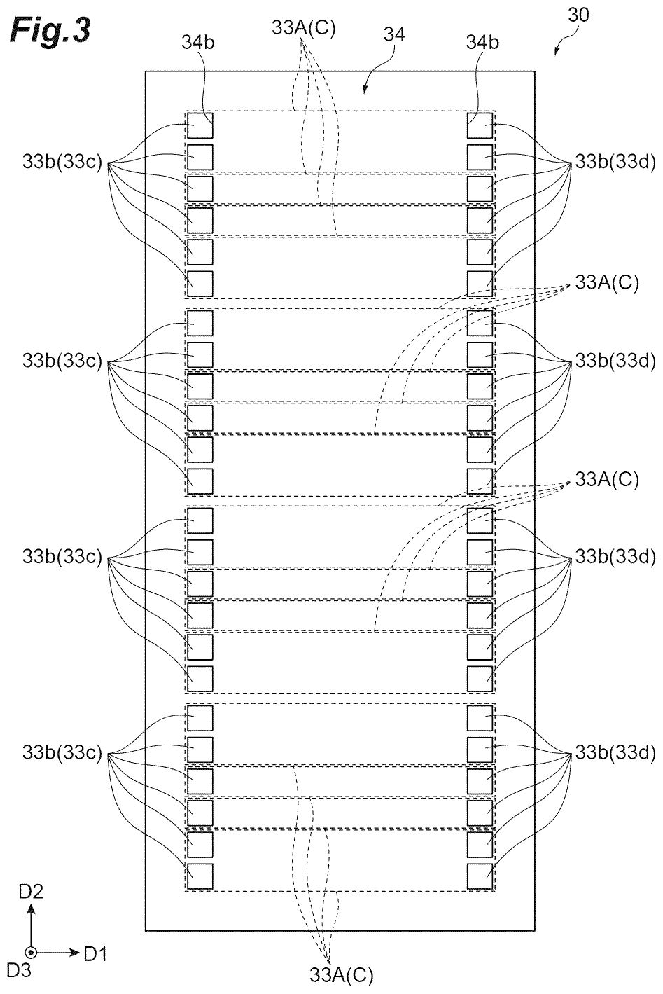

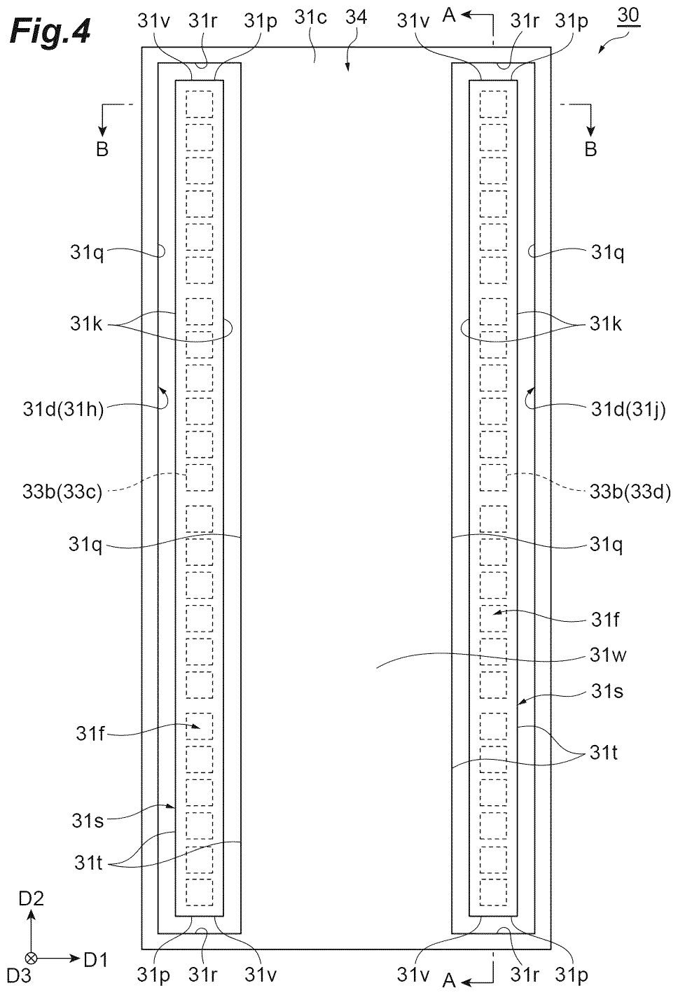

FIG. 3 is a bottom view showing the bridge chip 30. FIG. 4 is a plan view showing the bridge chip 30. As shown in FIGS. 2, 3, and 4, a pad 11f of the driver IC 11 is electrically connected to a pad 12c of the optical circuit element 12 via the bridge chip 30. The bridge chip 30 is connected to the driver IC 11 and the optical circuit element 12, and transmits an electrical signal. The electrical signal transmitted by the bridge chip 30 has, for example, a band of 100 GHz or more.

For example, the bridge chip 30 has a rectangular plate shape. For example, a length of the bridge chip 30 in the second direction D2 is larger than a length of the bridge chip 30 in the first direction D1, and the length of the bridge chip 30 in the first direction D1 is larger than a length of the bridge chip 30 in the third direction D3. As one example, the length of the bridge chip 30 in the second direction D2 is 2 mm or more and 4 mm or less, the length (width) of the bridge chip 30 in the first direction D1 is 0.5 mm or more and 2 mm or less, and the length (thickness) of the bridge chip 30 in the third direction D3 is 0.1 mm or more and 0.5 mm or less.

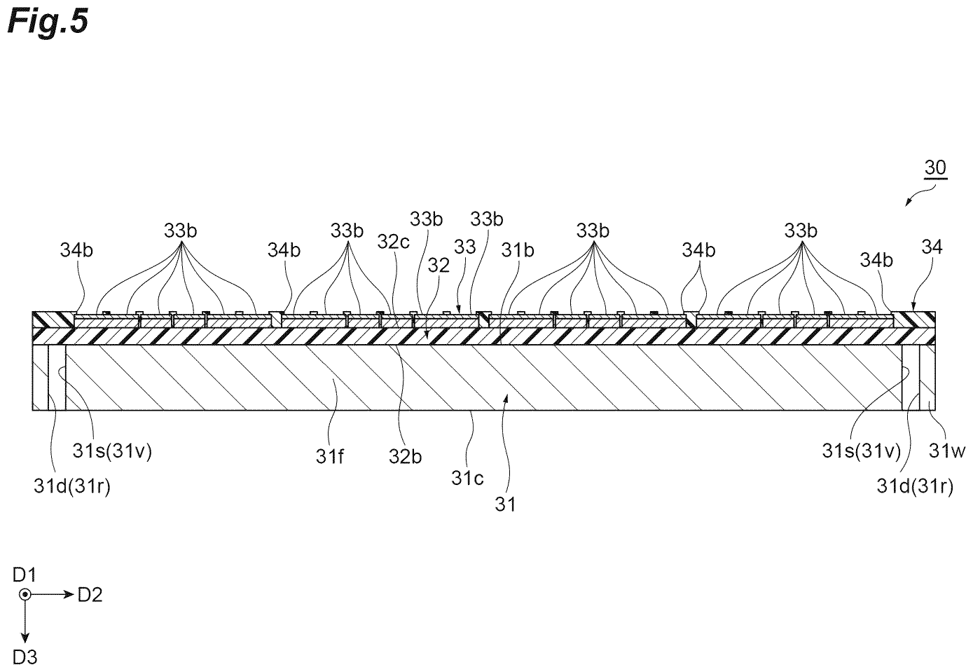

The bridge chip 30 includes a substrate 31, a first resin film 32, and a metal film 33. For example, when viewed along the third direction D3, the shape and size of the substrate 31 are the same as the shape and size of the first resin film 32. FIG. 5 is a cross-sectional view taken along line A-A of FIG. 4. As shown in FIGS. 3, 4, and 5, the substrate 31 has a first surface 31b and a second surface 31c opposite to the first surface 31b. The substrate 31 is made of silicon (Si). The substrate 31 has, for example, a rectangular plate shape. A length (thickness) of the substrate 31 in the third direction D3 is, for example, 0.2 mm.

The first resin film 32 has flexibility. For example, the flexibility of the first resin film 32 is higher than the flexibility of the substrate 31, and is higher than the flexibility of the metal film 33. The first resin film 32 is formed on the first surface 31b. The first resin film 32 is interposed between the first surface 31b of the substrate 31 and the metal film 33. The first resin film 32 has a third surface 32b with which the first surface 31b of the substrate 31 comes into contact, and a fourth surface 32c opposite to the third surface 32b. The metal film 33 comes into contact with the fourth surface 32c. The first resin film 32 has, for example, a rectangular plate shape. As one example, a length (thickness) of the first resin film 32 in the third direction D3 is 7 μm. For example, the first resin film 32 is made of polyimide. However, the first resin film 32 may be made of a material other than polyimide. For example, the first resin film 32 may be made of modified polyimide or polybenzoxazole.

The metal film 33 is formed on the first resin film 32. The metal film 33 has conductivity. The metal film 33 is in contact with the fourth surface 32c of the first resin film 32. As one example, a length (thickness) of the metal film 33 in the third direction D3 is 3 μm. In this case, since the metal film 33 is thin, the flexibility of the metal film 33 is increased. The metal film 33 includes a connecting portion 33b for an electrical connection with an element (for example, the driver IC 11 or the optical circuit element 12). For example, the connecting portion 33b is a pad.

For example, the bridge chip 30 includes a plurality of the metal films 33. In this case, the plurality of metal films 33 are aligned along the second direction D2. For example, the metal films 33 are made of copper (Cu). In this case, fine patterning is made possible through plating to be described later. However, the metal films 33 may be made of a material other than copper. For example, the metal films 33 may be made of gold (Au) or aluminum (Al). The connecting portion 33b of the metal film 33 is plated with, for example, Au. However, the connecting portion 33b may include an intermediate layer containing nickel (Ni) or palladium (Pd) between Au and Cu. The plurality of metal films 33 are in contact with the first resin film 32. The first resin film 32 has insulating properties. The plurality of metal films 33 are electrically insulated from each other.

For example, the bridge chip 30 includes a second resin film 34 formed on the first resin film 32 and the metal films 33. The second resin film 34 has flexibility. For example, the flexibility of the second resin film 34 is higher than the flexibility of the substrate 31, and is higher than the flexibility of the metal films 33. The second resin film 34 is in contact with the fourth surface 32c of the first resin film 32. The second resin film 34 has an opening 34b on each of the metal films 33. For example, a part of the metal film 33 is exposed through the opening 34b, and the part of the metal film 33, which is exposed through the opening 34b, serves as the connecting portion 33b.

The second resin film 34 has, for example, a rectangular plate shape. The second resin film 34 has a plurality of the openings 34b. The plurality of openings 34b are aligned along the second direction D2. For example, two openings 34b are aligned along the first direction D1. As one example, the openings 34b have a rectangular shape. For example, the second resin film 34 is made of polyimide. The material of the second resin film 34 may be the same as the material of the first resin film 32, or may be different from the material of the first resin film 32. The second resin film 34 may be made of a material other than polyimide. For example, the second resin film 34 may be made of modified polyimide or polybenzoxazole. The second resin film 34 come into contact with the plurality of metal films 33. The second resin film 34 has insulating properties. The plurality of metal films 33 are electrically insulated from each other. The second resin film 34 functions as a protection film that protects the plurality of metal films 33. The second resin film 34 can also be omitted.

The metal films 33 include wirings 33A. The wirings 33A extend along the first direction D1. Each of the wirings 33A includes two end portions. Each of the wirings 33A includes a first pad 33c formed as the connecting portion 33b at one end portion (first end portion), and a second pad 33d formed as the connecting portion 33b at the other end portion (second end portion). For example, the first pad 33c and the second pad 33d are disposed at both respective ends of each of the wirings 33A in the first direction D1.

For example, the first pad 33c is configured to be electrically connectable to the driver IC 11, and the second pad 33d is configured to be electrically connectable to the optical circuit element 12. In this case, the first pad 33c is connected to the pad 11f of the driver IC 11, and the second pad 33d is connected to the pad 12c of the optical circuit element 12. Hereinafter, a portion where the first pad 33c is connected to the pad 11f of the driver IC 11 and a portion where the second pad 33d is connected to the pad 12c of the optical circuit element 12 are referred to as joint portions. Each of the joint portions includes, for example, one of a stud bump 46 or a solder bump 62 to be described later. For example, the metal films 33 include a plurality of the wirings 33A, each extending in the first direction D1. The plurality of wirings 33A are disposed along the second direction D2. Therefore, a plurality of the first pads 33c are disposed along the second direction D2, and a plurality of the second pads 33d are disposed along the second direction D2.

The bridge chip 30 includes a group C made up of a plurality of the wirings 33A aligned along the second direction D2, and a plurality of the groups C are aligned along the second direction D2. As one example, the number of the wirings 33A constituting each of the groups C is four. For example, in the group C, one layer of coplanar lines having a ground-signal-signal-ground (GSSG) configuration is formed. In the bridge chip 30, for example, one layer of coplanar lines having the GSSG configuration are formed into four channels. The presence of two signals in each channel enables the transmission of differential signals. The configuration of the transmission line is not limited to GSSG, and may be, for example, ground-signal-ground signal-ground (GSGSG), signal-signal (SS), or signal-ground-signal (SGS). Further, in the bridge chip 30, two layers of microstrip lines may be formed instead of one layer of coplanar lines.

For example, a thickness (length in the second direction D2) of the ground wiring 33A is larger than a thickness of the signal wiring 33A, for example, twice as large as that of the signal wiring 33A. For example, the ground wiring 33A includes two first pads 33c aligned along the second direction D2, and two second pads 33d aligned along the second direction D2. For example, the signal wiring 33A includes one first pad 33c at an end portion in the first direction D1, and one second pad 33d at an end portion opposite to the first pad 33c.

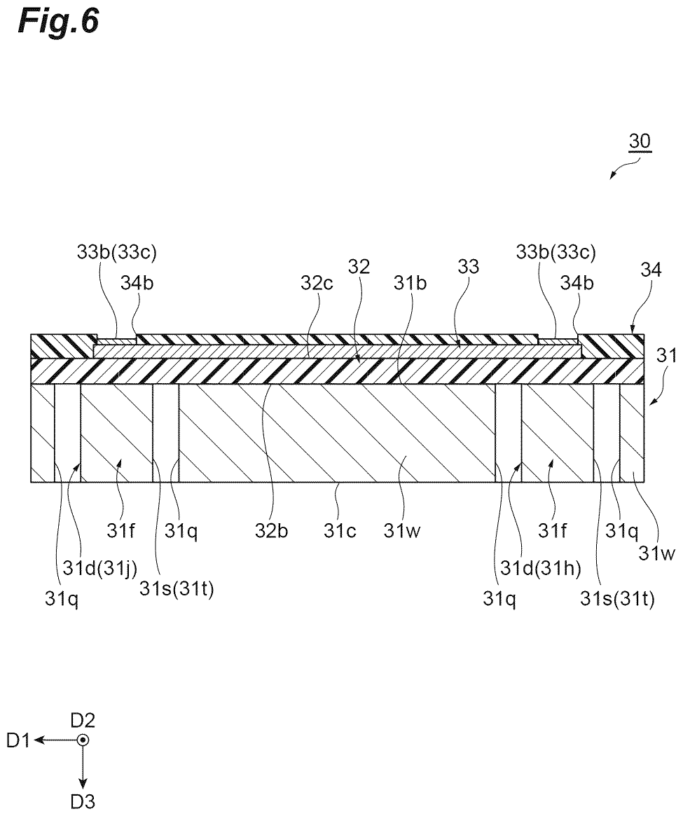

The substrate 31 includes a buffer portion 31d penetrating through the substrate 31 between the first surface 31b and the second surface 31c. FIG. 6 is a cross-sectional view taken along line B-B of FIG. 4. As shown in FIGS. 4, 5, and 6, the buffer portion 31d is, for example, a through-hole penetrating through the substrate 31 in the third direction D3. The through-hole is hollow. For example, in a plan view of the substrate 31 (when viewed along the third direction D3), the buffer portion 31d has a rectangular shape. A length of the buffer portion 31d in the second direction D2 is larger than a length of the buffer portion 31d in the first direction D1.

The connecting portion 33b is disposed inside the buffer portion 31d in a plan view of the substrate 31. Namely, when viewed in the third direction D3, a plurality of the connecting portions 33b are located inside the buffer portion 31d. The buffer portion 31d has, for example, first inner surfaces 31q extending in both the second direction D2 and the third direction D3, and second inner surfaces 31r extending in both the first direction D1 and the third direction D3. The buffer portion 31d is defined by a pair of the first inner surfaces 31q aligned along the first direction D1 and a pair of the second inner surfaces 31r aligned along the second direction D2.

For example, the buffer portion 31d includes a first buffer portion 31h and a second buffer portion 31j aligned along the first direction D1. In a plan view of the substrate 31, the first buffer portion 31h includes the plurality of first pads 33c thereinside, and the second buffer portion 31j includes the plurality of second pads 33d thereinside. In a plan view of the substrate 31, for example, each of the first buffer portion 31h and the second buffer portion 31j has a rectangular shape.

The substrate 31 includes a support portion 31f located inside the buffer portion 31d in a plan view of the substrate 31, and a general portion 31w that is a portion of the substrate 31 other than the support portion 31f. The support portion 31f is made of, for example, silicon. The support portion 31f is provided inside the buffer portion 31d, and is separated from the general portion 31w. Namely, in a plan view taken along the third direction D3, the support portion 31f is surrounded by the buffer portion 31d. The connecting portions 33b are connected to the second surface 31c of the substrate 31 via the first resin film 32 and the support portion 31f. The support portion 31f has first outer surfaces 31k extending in both the second direction D2 and the third direction D3, and second outer surfaces 31p extending in both the first direction D1 and the third direction D3. The support portion 31f has a pair of the first outer surfaces 31k aligned along the first direction D1, and a pair of the second outer surfaces 31p aligned along the second direction D2.

For example, the substrate 31 includes the support portion 31f and a groove 31s, which surrounds the support portion 31f, in the buffer portion 31d in a plan view of the substrate 31. As one example, a width of the groove 31s is 50 μm. The groove 31s is recessed from the second surface 31c along the third direction D3. The groove 31s penetrates through the substrate 31 in the third direction D3. The groove 31s has a rectangular frame shape in a plan view of the substrate 31. The groove 31s includes a first groove 31t formed between the first inner surface 31q and the first outer surface 31k, and a second groove 31v formed between the second inner surface 31r and the second outer surface 31p. The groove 31s include a pair of the first grooves 31t aligned along the first direction D1, and a pair of the second grooves 31v aligned along the second direction D2.

The support portion 31f is made independent of the general portion 31w by the groove 31s. Namely, the support portion 31f is separated from the general portion 31w. For example, the support portion 31f has an island shape independent of the general portion 31w. The connecting portions 33b of the metal films 33 are connected to the support portion 31f, which is independent of the general portion 31w, via the first resin film 32 inside the buffer portion 31d. Therefore, portions of the substrate 31 and the first resin film 32 where the connecting portions 33b are provided (portions of the substrate 31 and the first resin film 32 which overlap the connecting portions 33b in a plan view taken along the third direction D3) are easily displaced with respect to the surrounding general portion 31w since the first resin film 32, the metal films 33, and the second resin film 34 have flexibility. A portion of the second resin film 34, which overlaps the groove 31s in a plan view of the substrate 31, may be removed. By removing the portion of the second resin film 34, which overlaps the groove 31s in a plan view of the substrate 31, the portions of the substrate 31 and the first resin film 32 where the connecting portions 33b are provided are made to be more easily displaced with respect to the surrounding general portion 31w.

Portions of the substrate 31 and the first resin film 32 where the first pads 33c are provided (portions of the substrate 31 and the first resin film 32 which overlap the first pads 33c in a plan view taken along the third direction D3) are isolated from portions of the substrate 31 and the first resin film 32 where the second pads 33d are provided (portions of the substrate 31 and the first resin film 32 which overlap the second pads 33d in a plan view taken along the third direction D3) by being surrounded by the first buffer portion 31h and the second buffer portion 31j, respectively. Therefore, the portions of the substrate 31 and the first resin film 32 where the first pads 33c are provided and the portions of the substrate 31 and the first resin film 32 where the second pads 33d are provided can be displaced independently of each other. Therefore, even when the driver IC 11 or the heat sink block 13 connected to the first pads 33c, the optical circuit element 12, the spacers 14, or the TEC 15 connected to the second pads 33d, or the bottom wall 2h deforms (for example, expands or contracts) due to a change in temperature or the like, the portions where the first pads 33c are provided and the portions where the second pad 33d are provided are flexibly displaced in response to the deformation. For example, when the distance between the first pads 33c and the second pads 33d is shortened due to deformation, the distance between the portions of the substrate 31 and the first resin film 32 where the first pads 33c are provided and the portions of the substrate 31 and the first resin film 32 where the second pads 33d are provided are also shortened. In addition, when the distance between the first pads 33c and the second pads 33d is lengthened due to deformation, the distance between the portions of the substrate 31 and the first resin film 32 where the first pads 33c are provided and the portions of the substrate 31 and the first resin film 32 where the second pads 33d are provided are also lengthened. Therefore, the joint portions between the driver IC 11 and the bridge chip 30, the joint portions between the optical circuit element 12 and the bridge chip 30, and the like can be protected from the influence of stress.

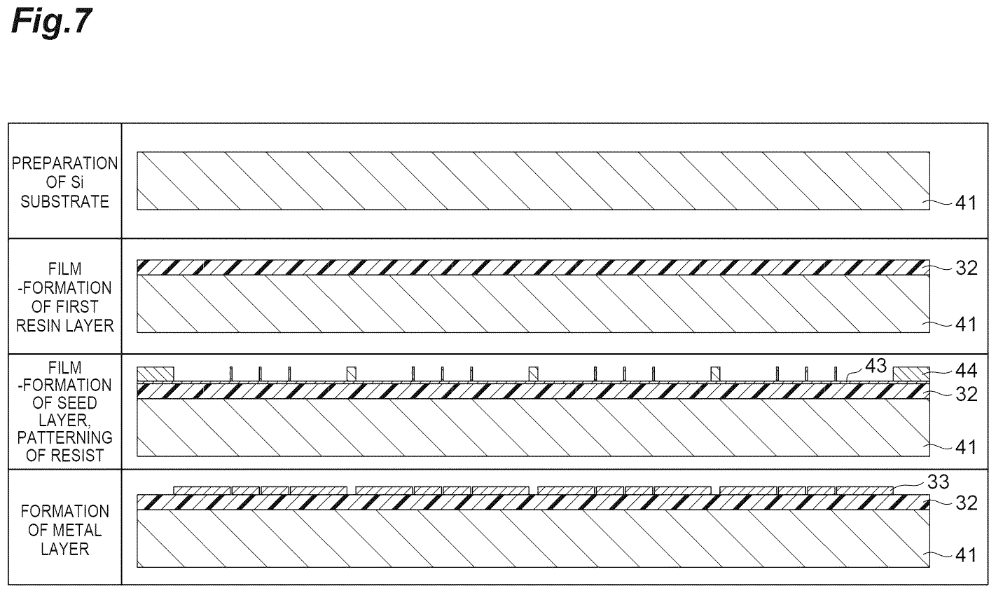

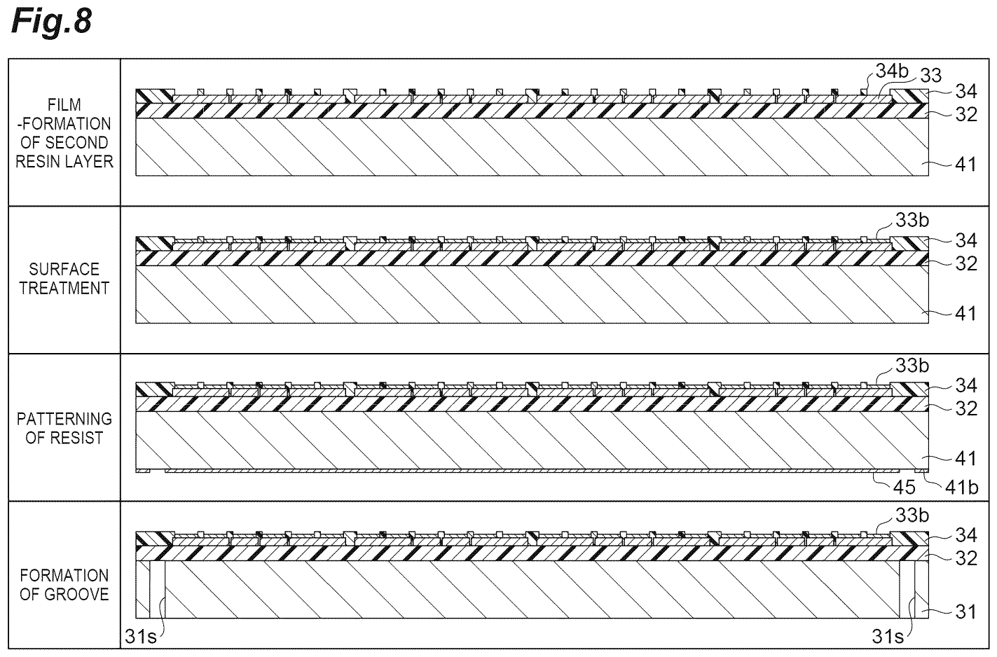

Next, an example of a method for manufacturing the bridge chip 30 will be described with reference to FIGS. 7 and 8. First, a Si substrate 41 serving as the base of the substrate 31 is prepared (a step of preparing a Si substrate). For example, the Si substrate 41 has a wafer shape (as one example, an 8-inch wafer). Next, the first resin film 32 is film-formed on the Si substrate 41 (a step of film-forming a first resin film). When the first resin film 32 is film-formed, a baking process may be performed.

After the first resin film 32 is film-formed, a seed layer 43 is film-formed (a step of film-forming a seed layer). The seed layer 43 is made of, for example, copper (Cu). The seed layer 43 is film-formed by sputtering. Thereafter, a resist 44 is film-formed on the seed layer 43, and is patterned (a step of patterning a resist). After the resist 44 is patterned, the metal film 33 is formed by performing electroplating to grow a plating on the seed layer 43 where there is no resist 44 (a step of forming a metal film). Then, the resist 44 is removed, and the seed layer 43 covered with the resist 44 is etched (for example, Cu etching).

Next, the second resin film 34 is film-formed on the first resin film 32 and the metal film 33 (a step of forming a second resin film). At this time, the plurality of openings 34b through which the metal film 33 is exposed are formed by patterning the second resin film 34 through exposure and development (a step of forming openings). Then, portions of the metal film 33 exposed through the openings 34b are subjected to a surface treatment. More specifically, a plating made of gold (Au), nickel (Ni) or palladium (Pd) is formed on the portions of the metal film 33 exposed through the openings 34b (a step of forming a plating). Accordingly, the connecting portions 33b are formed.

Then, a resist 45 is film-formed on a surface 41b on an opposite side of the Si substrate 41 from the first resin film 32, and is patterned. After the resist 45 is patterned, the groove 31s is formed by performing etching (for example, Si etching) (a step of forming a groove). For example, deep etching is performed using Deep RIE to form the groove 31s. The buffer portion 31d and the support portion 31f are formed by the formation of the groove 31s. Then, after the resist 45 is removed and dicing is performed, a series of the steps for manufacturing the bridge chip 30 is completed.

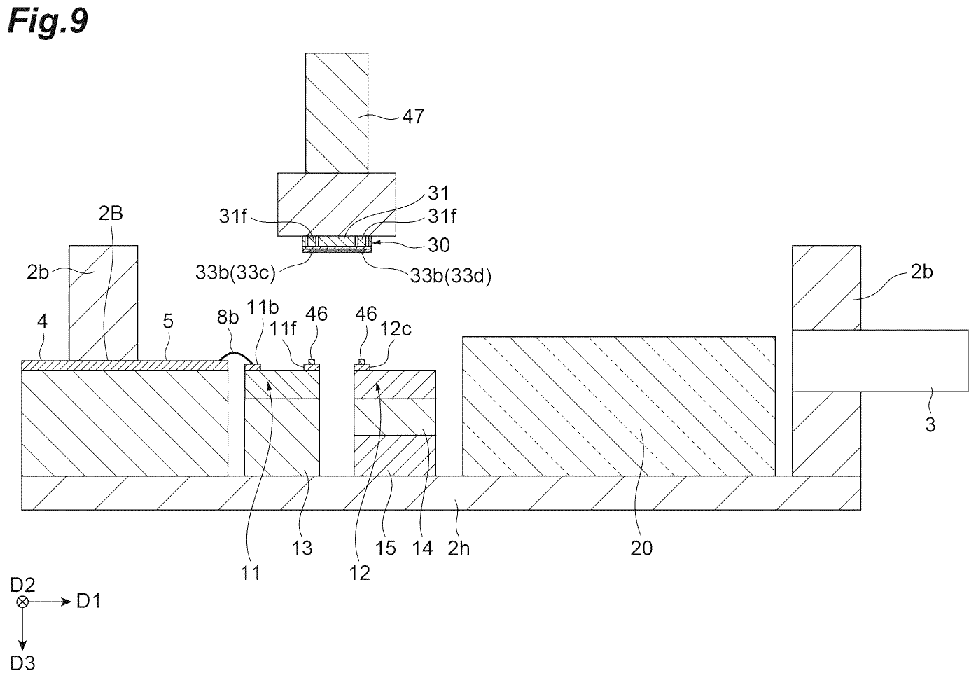

Next, an example of a method for manufacturing the semiconductor integrated module 1 will be described with reference to FIG. 9. First, in a package including the bottom wall 2h, the first side walls 2b, and the second side walls 2c, the heat sink block 13, the driver IC 11, the TEC 15, the spacers 14, the optical circuit element 12, and the optical component 20 are mounted on the bottom wall 2h. The stud bumps 46 are formed on the pads 11f of the driver IC 11 and the pads 12c of the optical circuit element 12 (a step of forming stud bumps). For example, the stud bumps 46 are Au stud bumps. In the package, the bottom wall 2h, the first side walls 2b, and the second side walls 2c may be integrally formed.

For example, the bridge chip 30 is held by a collet 47 in a state where the connecting portions 33b of the metal films 33 face downward. Then, the connecting portions 33b are brought into contact with the respective stud bumps 46, and the bridge chip 30 is flip-chip mounted on the driver IC 11 and the optical circuit element 12 by thermocompression bonding. At this time, since the connecting portions 33b are supported at a tip of the collet 47 via the support portion 31f, a load and heat can be applied to each of the stud bumps 46. The bridge chip 30 may be mounted on the driver IC 11 and the optical circuit element 12 by ultrasonic joining instead of the thermocompression bonding. After the bridge chip 30 is mounted, the lid 6 is disposed on the first side walls 2b and the second side walls 2c to seal the internal space 2A, and then a series of the steps for manufacturing the semiconductor integrated module 1 is completed. Before the internal space 2A is sealed with the lid 6, the mounting of the optical component 20, the wiring of the bonding wires 8b, and the like are performed.

Next, actions and effects obtained from the bridge chip 30 and the semiconductor integrated module 1 according to the present embodiment will be described. The bridge chip 30 includes the first resin film 32 having flexibility between the substrate 31 and the metal films 33. The metal films 33 include the connecting portions 33b for electrical connections with each of the driver IC 11 and the optical circuit element 12. The substrate 31 includes the buffer portion 31d penetrating through the substrate 31, and the connecting portions 33b are disposed inside the buffer portion 31d in a plan view of the substrate 31. Therefore, the connecting portions 33b, the first resin film 32 having flexibility, and the buffer portion 31d are aligned in order along the third direction D3 that is a lamination direction of the substrate 31, the first resin film 32, and the metal films 33. Portions where the connecting portions 33b are located in a plan view of the substrate 31 can be displaced with respect to other portions of the bridge chip 30 since the connecting portions 33b are separated from the surrounding substrate 31 (general portion 31w) by the buffer portion 31d.

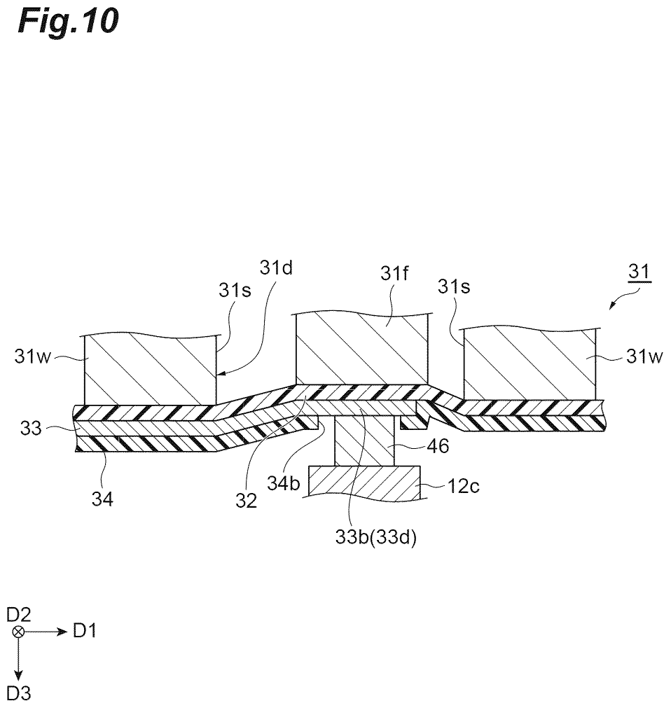

FIG. 10 is a view schematically showing a displacement of a portion of the buffer portion 31d where the connecting portion 33b connected to the pad 12c of the optical circuit element 12 is located. As shown in FIG. 10, since portions of the substrate 31 (support portion 31f) and the first resin film 32 which are aligned with the connecting portion 33b along the third direction D3 are independent of the general portion 31w of the substrate 31, the first resin film 32, the metal film 33, and the second resin film 34 deform to be displaceable with respect to the surrounding general portion 31w inside the buffer portion 31d. As one example, when a thickness (width) of the groove 31s is 50 μm, the portion aligned with the connecting portion 33b along the third direction D3 can be displaced by approximately 10 μm. FIG. 10 shows the displacement of the portion where the second pad 33d connected to the pad 12c of the optical circuit element 12 is located; however, a portion where the first pad 33c connected to the pad 11f of the driver IC 11 is located can also be displaced in the same manner.

Since the connecting portions 33b that are electrically connected to each of the driver IC 11 and the optical circuit element 12 can be displaced with respect to other portions of the bridge chip 30, even when a change in temperature or the like occurs and each of the pads 11f of the driver IC 11 and the pads 12c of the optical circuit element 12 is displaced, the influence of stress on the joint portions between the driver IC 11 and the bridge chip 30 and the joint portions between the optical circuit element 12 and the bridge chip 30 can be reduced. Therefore, the robustness of electrical connections between the driver IC 11 and the optical circuit element 12 can be improved. For example, in a case where there is no buffer portion 31d, the relative positions of the connecting portions 33b connected to the driver IC 11 and the connecting portions 33b connected to the optical circuit element 12 are fixed, so that the joint portions between the driver IC 11 and the bridge chip 30 and the joint portions between the optical circuit element 12 and the bridge chip 30 are subjected to stress when each of the pads 11f of the driver IC 11 and the pads 11f of the optical circuit element 12 is displaced.

Further, in the present embodiment, the portions of the substrate 31 and the first resin film 32 where the first pads 33c are provided and the portions of the substrate 31 and the first resin film 32 where the second pads 33d are provided are isolated from the general portion 31w by the formation of the groove 31s. Therefore, thermal insulation for the first pads 33c and the second pads 33d can be improved. As a result of performing thermal analysis on the bridge chip 30 including the substrate 31 in which the groove 31s having a width of 50 μm was formed, and a bridge chip including a substrate in which the groove 31s was not formed, a thermal resistance between the first pads 33c and the second pads 33d in the bridge chip in which the groove 31s was not formed was 104.4 [K/W], whereas the thermal resistance in the bridge chip 30 in which the groove 31s was formed was 202.6 [K/W].

The bridge chip 30 may be the second resin film 34 having flexibility and may include the second resin film 34 that is formed on the first resin film 32 and the metal films 33, and that has the openings 34b on the metal films 33. In this case, a part of the first resin film 32 and a part of the metal films 33 can be covered with the second resin film 34 having flexibility. The second resin film 34 functions as a protection film for the metal films 33.

The substrate 31 may further include the support portion 31f inside the buffer portion 31d in a plan view of the substrate 31. The connecting portions 33b may be connected to the second surface 31c of the substrate 31 via the first resin film 32 and the support portion 31f. In this case, the connecting portions 33b, the first resin film 32 having flexibility, and the support portion 31f are aligned in order along the third direction D3. Therefore, the first resin film 32 and the connecting portions 33b can be supported by the support portion 31f while the portions of the first resin film 32 which are aligned with the connecting portions 33b along the third direction D3 are deformed. Accordingly, for example, when the bridge chip 30 is gripped by the collet 47, and is mounted on the driver IC 11 and the optical circuit element 12, a load and heat can be effectively applied to join the connecting portions 33b to the pads 11f.

The first resin film 32 may be made of polyimide. In this case, the first resin film 32 can be a resin film having excellent flexibility and stretchability.

The metal films 33 may be made of any of copper (Cu), gold (Au), and aluminum (Al).

Each of the metal films 33 may include the wiring 33A having a shape extending in the first direction D1 and including two end portions. The one end portion (first end portion) of the wiring 33A includes the first pad 33c formed as the connecting portion 33b, and the other end portion (second end portion) of the wiring 33A includes the second pad 33d formed as the connecting portion 33b. The first pad 33c may be configured to be electrically connectable to the driver IC 11, and the second pad 33d may be configured to be electrically connectable to the optical circuit element 12 isolated from the driver IC 11. In this case, the first pad 33c of the wiring 33A of the metal film 33 can be electrically connected to the driver IC 11, and the second pad 33d of the wiring 33A of the metal film 33 can be electrically connected to the optical circuit element 12. Accordingly, an electrical signal can be transmitted from the driver IC 11 to the optical circuit element 12 via the wiring 33A.

The metal films 33 may include the plurality of wirings 33A, each extending in the first direction D1, and each of the plurality of wirings 33A includes two end portions. Each of the wirings 33A may include the first pad 33c at the one end portion (first end portion), and each of the wirings 33A may include the second pad 33d at the other end portion (second end portion). The first pads 33c of a plurality of the wirings 33A may be disposed along the second direction D2, and the second pads 33d of a plurality of the wirings 33A may be disposed along the second direction D2. The plurality of wirings 33A are insulated from each other. The buffer portion 31d may include the first buffer portion 31h including the plurality of first pads 33c thereinside in a plan view of the substrate 31, and the second buffer portion 31j including the plurality of second pads 33d thereinside in a plan view of the substrate 31. In this case, the first pad 33c and the portion of the first resin film 32 which is aligned with the first pad 33c along the third direction D3, and the second pad 33d and the portion of the first resin film 32 which is aligned with the second pad 33d along the third direction D3 can be displaced relative to each other.

The substrate 31 may be made of silicon. In addition, the support portion 31f of the substrate 31 may be made of silicon. In this case, the heating of the substrate 31 can be easily performed during mounting or the like. In addition, the formation of the groove 31s can be easily performed by etching.

Next, bridge chips according to modification examples will be described. A configuration of a part of bridge chips according to various modification examples to be described later is the same as a configuration of a part of the bridge chip 30 described above. Therefore, in the following description, configurations that overlap with those of the bridge chip 30 are denoted by the same reference signs, and description thereof will be omitted as appropriate.

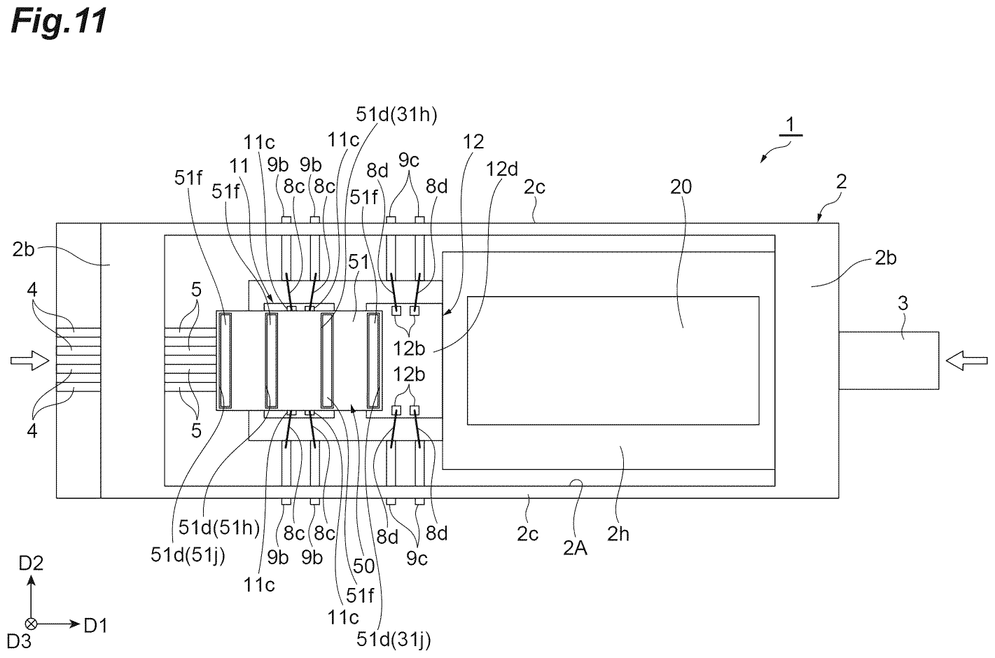

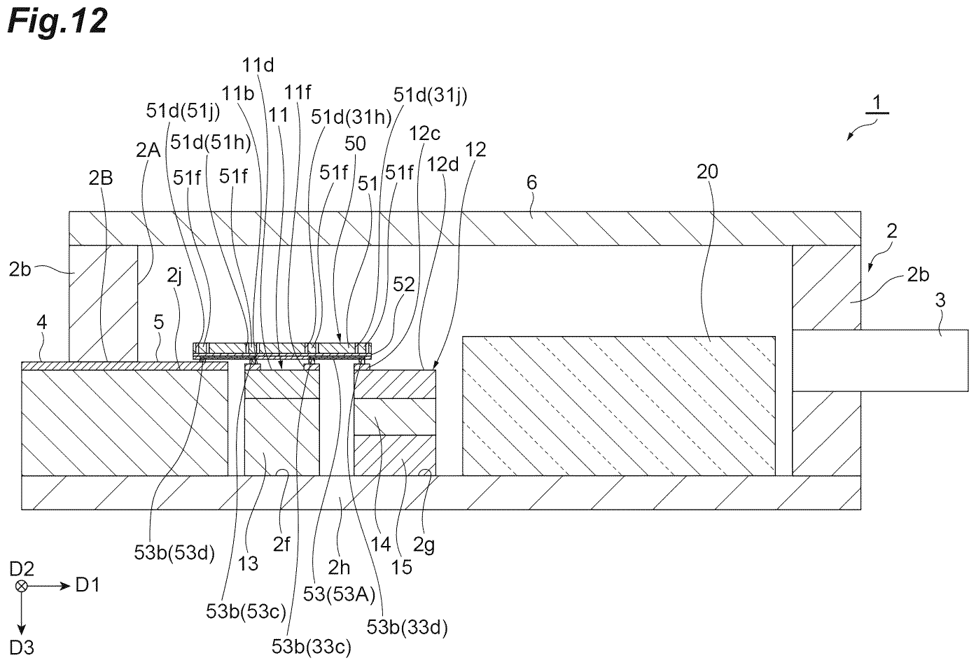

FIG. 11 is a plan view showing an internal structure of a semiconductor integrated module including a bridge chip 50 according to a first modification example. FIG. 12 is a cross-sectional view of the semiconductor integrated module of FIG. 11 taken along a plane extending along both the first direction D1 and the third direction D3. As shown in FIGS. 11 and 12, the bridge chip 50 extends from the optical circuit element 12 across the driver IC 11 to the package 2.

The bridge chip 50 includes a substrate 51, a first resin film 52, and a metal film 53. The first resin film 52 is the same as the first resin film 32, for example, except for a length of the first resin film 52 in the first direction D1. The metal film 53 includes a wiring 53A, and the wiring 53A includes the first pad 33c, the second pad 33d, a third pad 53c, and a fourth pad 53d as connecting portions 53b. The third pad 53c is configured to be electrically connectable to the driver IC 11, and the fourth pad 53d is configured to be electrically connectable to the package 2. More specifically, the third pad 53c is connected to the pad 11b of the driver IC 11, and the fourth pad 53d is connected to the terminal 5 formed on the fifth surface 2j of the package 2.

The substrate 51 includes a buffer portion 51d and a support portion 51f. For example, the shape and size of the buffer portion 51d are the same as the shape and size of the buffer portion 31d described above, and the shape and size of the support portion 51f are the same as the shape and size of the support portion 31f described above. The buffer portion 51d includes the first buffer portion 31h, the second buffer portion 31j, a third buffer portion 51h, and a fourth buffer portion 51j. In a plan view of the substrate 51, the third buffer portion 51h includes a plurality of the third pads 53c thereinside, and the fourth buffer portion 51j includes a plurality of the fourth pads 53d thereinside.

As described above, in the bridge chip 50 according to the first modification example, the substrate 51 includes the buffer portion 51d penetrating through the substrate 51, and the connecting portions 53b are disposed inside the buffer portion 51d in a plan view of the substrate 51. Therefore, portions where the connecting portions 53b are located in a plan view of the substrate 51 can be displaced with respect to other portions of the bridge chip 50 by the deformation of the first resin film 32 therearound. Since the connecting portions 53b that are electrically connected to each of the driver IC 11, the optical circuit element 12, and the package 2 are configured to be displaceable relative to each other, the influence of stress on joint portions between the package 2 and the bridge chip 50, joint portions between the driver IC 11 and the bridge chip 50, and joint portions between the optical circuit element 12 and the bridge chip 50 can be reduced. Therefore, the same actions and effects as those of the bridge chip 30 can be obtained from the bridge chip 50. Further, the bridge chip 50 extends from the optical circuit element 12 over the driver IC 11 to the package 2, so that the need for the bonding wires 8b connecting the package 2 and the driver IC 11 to each other can be eliminated.

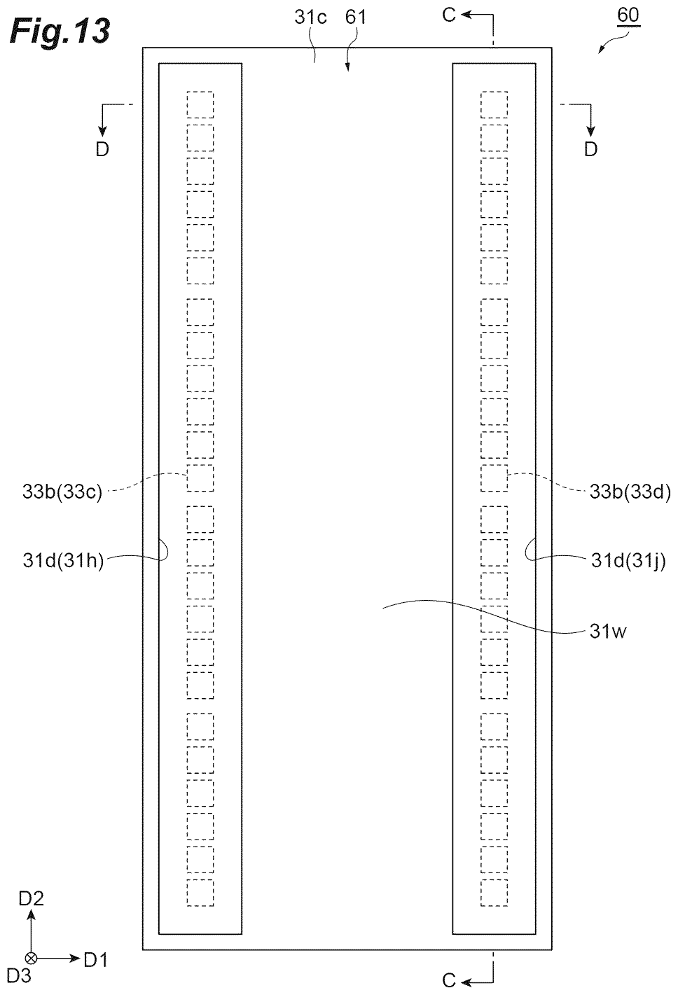

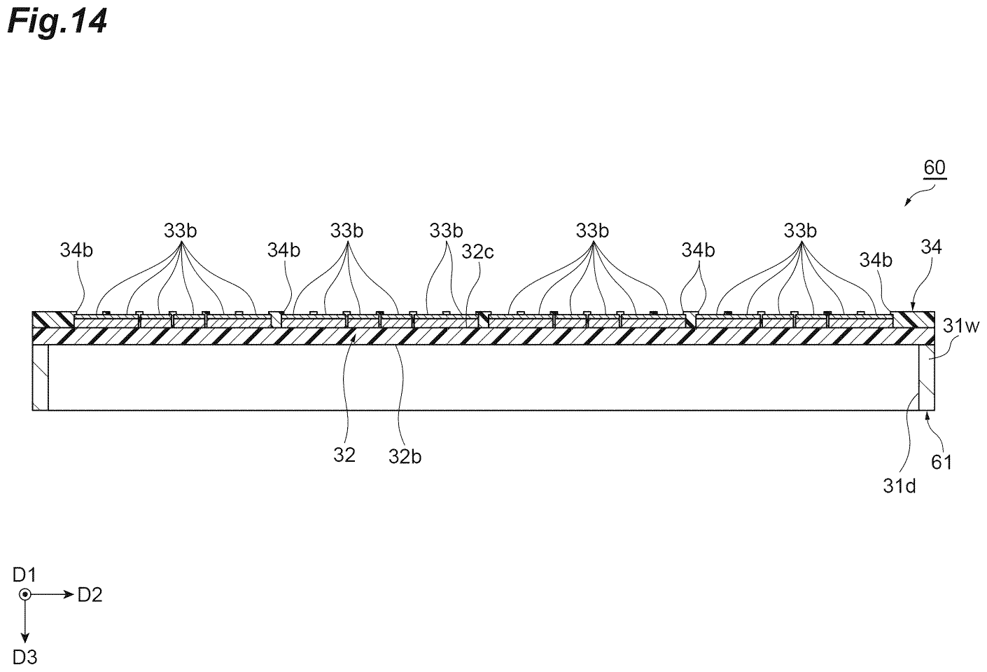

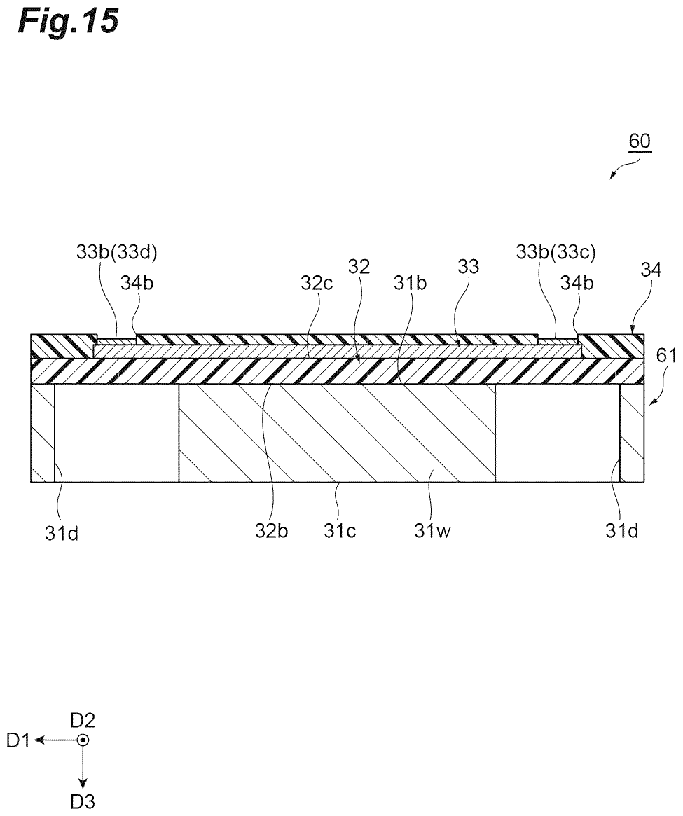

FIG. 13 is a plan view showing a bridge chip 60 according to a second modification example. FIG. 14 is a cross-sectional view taken along line C-C of FIG. 13. FIG. 15 is a cross-sectional view taken along line D-D of FIG. 13. As shown in FIGS. 13, 14, and 15, the bridge chip 60 includes a substrate 61 that does not include the support portion 31f. Therefore, at locations from the connecting portions 33b along the third direction D3, the first resin film 32 is provided but the substrate 61 is not provided. Therefore, in the bridge chip 60, portions of the first resin film 32 where the connecting portions 33b are provided (portions of the first resin film 32 which overlap the connecting portions 33b in a plan view taken along the third direction D3) are much more easily displaced with respect to the surrounding general portion 31w than in the case of the bridge chip 30.

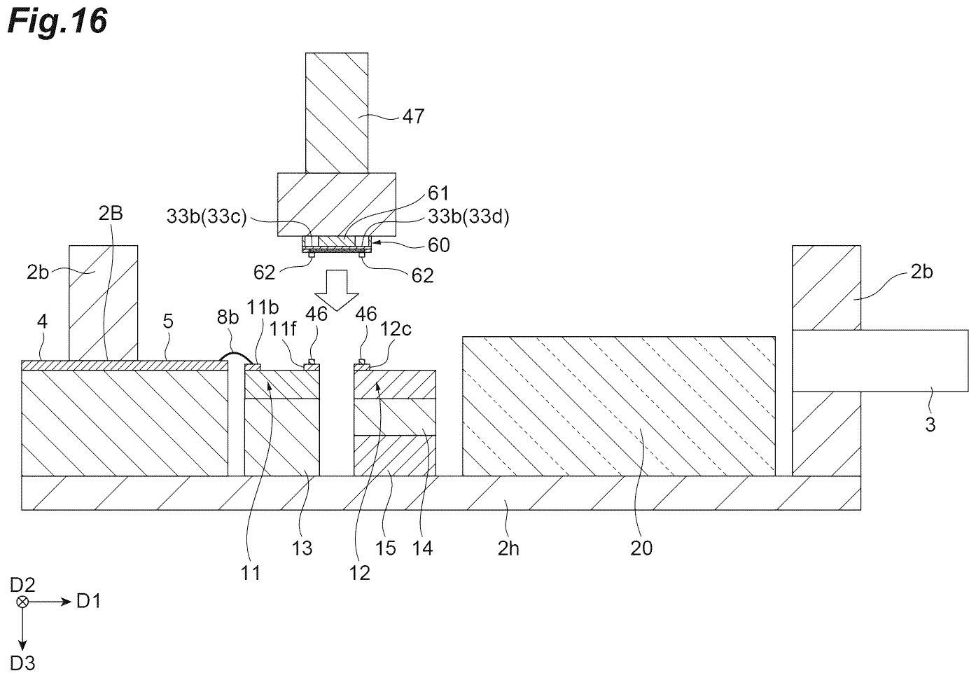

FIG. 16 is a view for describing the mounting of the bridge chip 60 on the driver IC 11 and the optical circuit element 12. As shown in FIG. 16, the bridge chip 60 includes the solder bumps 62 formed on the connecting portions 33b. The solder bumps 62 are made of, for example, tin-silver-copper (SnAgCu) or gold-tin (AuSn). For example, the bridge chip 60 is held by the collet 47 in a state where the solder bumps 62 face downward. Then, the bridge chip 60 is flip-chip mounted on the driver IC 11 and the optical circuit element 12 by bringing each of the solder bumps 62 into contact with the stud bump 46, and heating and melting the solder bumps 62.

As described above, in the bridge chip 60 according to the second modification example, the first resin film 32 is provided at locations from the connecting portions 33b along the third direction D3, but the substrate 61 (support portion 31f) is not provided. Therefore, since the portions of the first resin film 32 where the connecting portions 33b are provided can deform more easily, even when a change in temperature or the like occurs, the influence of stress on joint portions between the driver IC 11 and the bridge chip 60 and joint portions between the optical circuit element 12 and the bridge chip 60 can be more reliably reduced. Further, the bridge chip 60 includes the solder bumps 62 formed on the connecting portions 33b. In this case, the connecting portions 33b can be connected to each of the driver IC 11 and the optical circuit element 12 by heating and melting the solder bumps 62. Therefore, the connecting portions 33b can be connected to the driver IC 11 and the optical circuit element 12 without pressing the connecting portions 33b against the driver IC 11 and the optical circuit element 12 via the support portion 31f during connection.

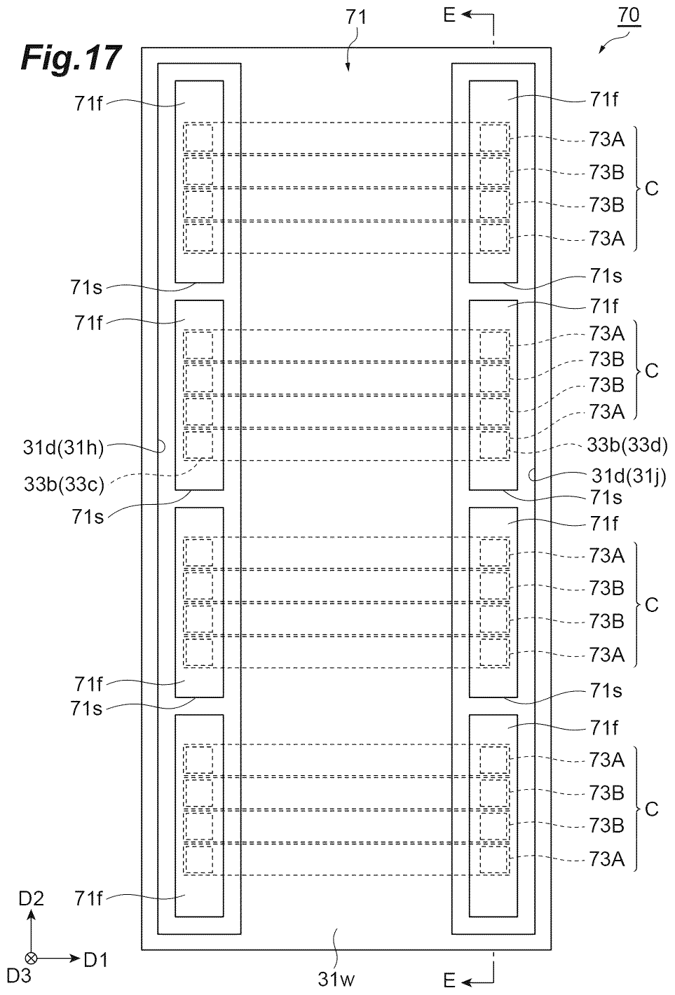

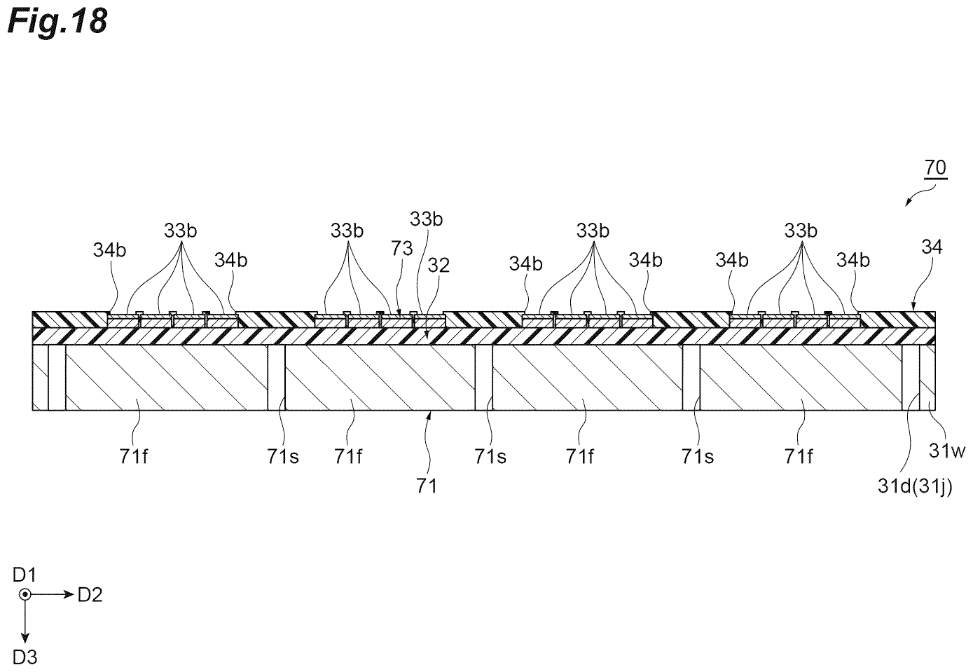

FIG. 17 is a plan view showing a bridge chip 70 according to a third modification example. FIG. 18 is a cross-sectional view taken along line E-E of FIG. 17. As shown in FIGS. 17 and 18, the bridge chip 70 includes a substrate 71 in which a plurality of support portions 71f are formed inside each of the first buffer portion 31h and the second buffer portion 31j; the first resin film 32; and a metal film 73. In the bridge chip 70, for example, one layer of coplanar lines having a GSSG configuration are formed into four channels. The metal film 73 includes a ground wiring 73A and a signal wiring 73B, and for example, a thickness of the ground wiring 73A is approximately the same as a thickness of the signal wiring 73B.

The substrate 71 includes the plurality of support portions 71f aligned along the second direction D2. The support portion 71f is provided, for example, for each channel. The bridge chip 70 includes the group C made up of a plurality of GSSG wirings aligned along the second direction D2, and the support portion 71f is provided for each group C. In a plan view of the substrate 71, a groove 71s is formed between two groups C aligned along the second direction D2. The plurality of support portions 71f are separated from each other by the grooves 71s.

As described above, in the bridge chip 70 according to the third modification example, the substrate 71 includes the plurality of support portions 71f separated from each other, and the support portion 71f is provided for each channel. Therefore, portions where the connecting portions 33b are located in a plan view of the substrate 71 can be displaced independently for each channel. In the third modification example, the example in which the divided support portion 71f is provided for each channel has been described. However, the support portion 71f may not be provided for each channel, and the mode in which the support portions 71f are separated is not particularly limited. Namely, in the third modification example, the plurality of support portions 71f are configured by dividing one support portion 31f into four segments for each channel; however, the plurality of support portions 71f may be configured by dividing one support portion 31f into two or three segments, and the number of divisions by which one support portion 31f is divided into the plurality of support portions 71f may be five or more.

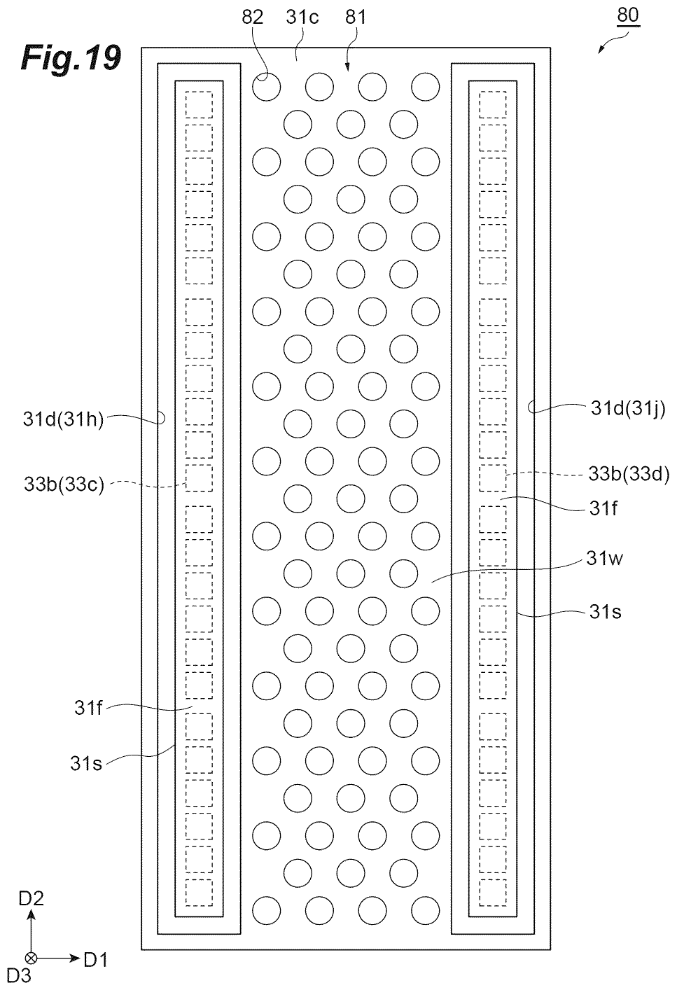

FIG. 19 is a plan view showing a bridge chip 80 according to a fourth modification example. The bridge chip 80 includes a substrate 81 in which a hole 82 located between the first buffer portion 31h and the second buffer portion 31j and recessed from the second surface 31c along the third direction D3 is formed. The substrate 81 has a plurality of the holes 82, and for example, the holes 82 penetrate through the substrate 81 in the third direction D3. In a plan view of the substrate 81, for example, the plurality of holes 82 are disposed in a staggered pattern. However, the disposition mode of the plurality of holes 82 is not particularly limited. In the bridge chip 80, the holes 82 are formed between the first buffer portion 31h and the second buffer portion 31j in a plan view of the substrate 81. Therefore, thermal insulation between the connecting portions 33b (first pads 33c) inside the first buffer portion 31h and the connecting portions 33b (second pads 33d) inside the second buffer portion 31j can be improved. Therefore, for example, the inflow of heat from the driver IC 11 to the optical circuit element 12 via the bridge chip 80 (such a phenomenon is referred to as thermal crosstalk) can be reduced.

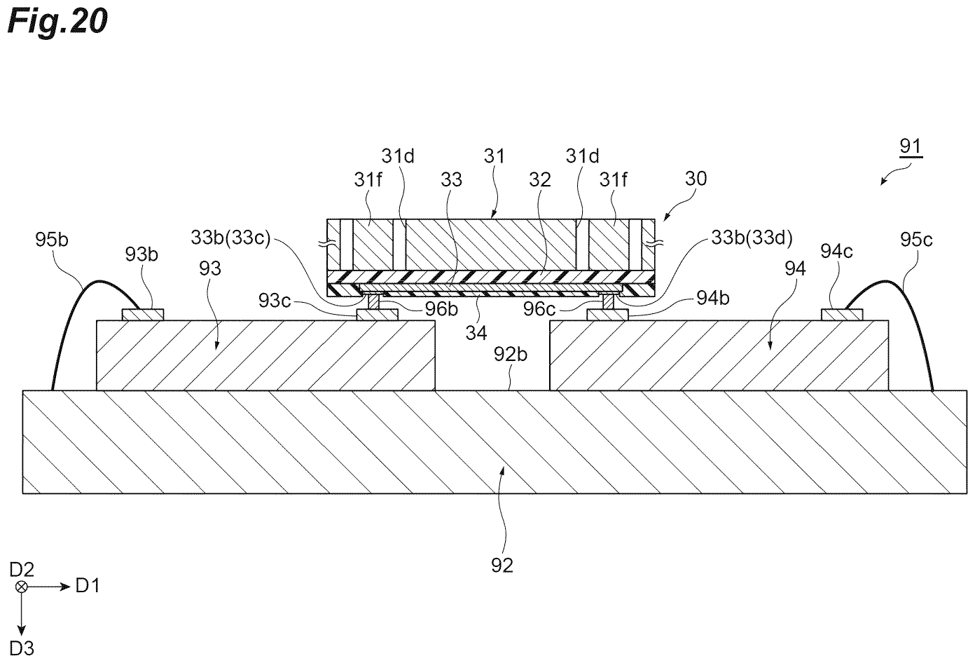

FIG. 20 is a cross-sectional view showing a semiconductor integrated module 91 according to a fifth modification example. As shown in FIG. 20, the semiconductor integrated module 91 includes a base 92 having a reference surface 92b; a first element 93 and a second element 94 mounted on the reference surface 92b; and the bridge chip 30 described above. For example, the first element 93 is an element that transmits an electrical signal, and the second element 94 is an element that receives an electrical signal. For example, the semiconductor integrated module 91 is not an optical module, and the semiconductor integrated module 91 does not require impedance control as in the semiconductor integrated module 1 described above.

The base 92 is, for example, a package substrate made of an organic material. The first element 93 includes a first pad 93b and a second pad 93c formed on a surface facing opposite to the base 92. The second element 94 includes a third pad 94b and a fourth pad 94c formed on a surface facing opposite to the base 92. The first element 93 and the second element 94 are mounted face-up on the base 92. For example, the semiconductor integrated module 91 includes a first bonding wire 95b and a second bonding wire 95c. The first bonding wire 95b electrically connects a pad (not shown) of the base 92 and the first pad 93b to each other, and the second bonding wire 95c electrically connects a pad (not shown) of the base 92 and the fourth pad 94c to each other. The connecting portion 33b (first pad 33c) of the bridge chip 30 is connected to the second pad 93c via a stud bump 96b, and the connecting portion 33b (second pad 33d) of the bridge chip 30 is connected to the third pad 94b via a stud bump 96c.

As described above, since the semiconductor integrated module 91 according to the fifth modification example includes the bridge chip 30 described above, the same effects as those described above are achieved. Namely, the connecting portion 33b connected to the first element 93 and the connecting portion 33b connected to the second element 94 can be displaced relative to each other. Therefore, even when a change in temperature or the like occurs, portions of the first resin film 32 which are aligned with the connecting portions 33b along the third direction D3 are displaced, so that the influence of stress on joint portions between the first element 93 and the bridge chip 30 and joint portions between the second element 94 and the bridge chip 30 can be reduced. Therefore, the robustness of electrical connections between the first element 93 and the second element 94 can be improved.

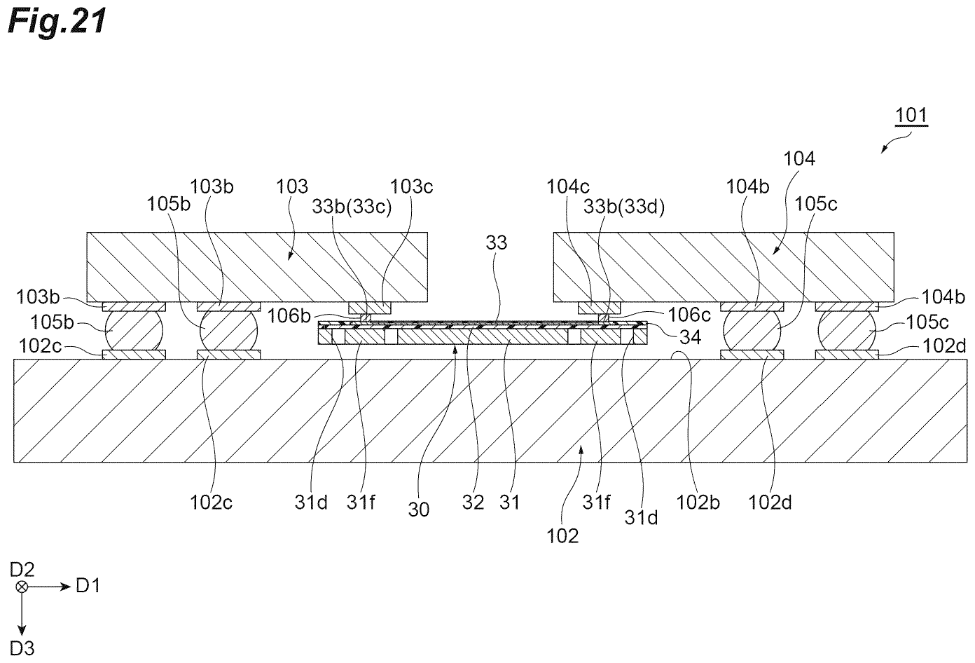

FIG. 21 is a cross-sectional view showing a semiconductor integrated module 101 according to a sixth modification example. As shown in FIG. 21, the semiconductor integrated module 101 includes a base 102 having a reference surface 102b; a first element 103 and a second element 104 mounted on the reference surface 102b; and the bridge chip 30 described above. For example, the first element 103 is an element that transmits an electrical signal, and the second element 104 is an element that receives an electrical signal. When viewed along the third direction D3, the bridge chip 30 is disposed between the first element 103 and the second element 104.

The base 102 is, for example, a package substrate made of an organic material. The base 102 includes a pad 102c disposed at a position facing the first element 103 on the reference surface 102b, and a pad 102d disposed at a position facing the second element 104 on the reference surface 102b. For example, the base 102 includes a plurality of the pads 102c and a plurality of the pads 102d. The plurality of pads 102c and the plurality of pads 102d are aligned along the reference surface 102b.

The first element 103 includes a first pad 103b and a second pad 103c formed on a surface facing the base 102. The second element 104 includes a third pad 104b and a fourth pad 104c formed on a surface facing the base 102. The semiconductor integrated module 101 includes a first terminal 105b and a second terminal 105c for surface mounting which are provided on the pad 102c and the pad 102d of the base 102, respectively. The first terminal 105b electrically connects the pad 102c and the first pad 103b to each other, and the second terminal 105c electrically connects the pad 102d and the third pad 104b to each other. Namely, the first element 103 and the second element 104 are mounted face-down on the base 102. Face-down mounting is also referred to as flip-chip mounting.

In the semiconductor integrated module 101, the bridge chip 30 is disposed such that the substrate 31 faces the base 102 and the connecting portions 33b face the first element 103 and the second element 104. Namely, the bridge chip 30 is disposed such that the connecting portions 33b face upward and the substrate 31 faces downward. The substrate 31 faces the base 102. The bridge chip 30 extends between the base 102 and each of the first element 103 and the second element 104 in both the first direction D1 and the second direction D2. The connecting portion 33b (first pad 33c) is connected to the second pad 103c, for example, via a stud bump 106b, and the connecting portion 33b (second pad 33d) is connected to the fourth pad 104c, for example, via a stud bump 106c. A solder bump may be used instead of the stud bump 106c. For example, the bridge chip 30 is connected to the first element 103 and the second element 104 by face-down mounting in a state where the bridge chip 30 is disposed face-up on a base of an assembly jig. The first element 103 and the second element 104 to which the bridge chip 30 is connected are mounted upside down on the base 102.

Subsequently, a bridge chip according to a seventh modification examples will be described. The shape and size of the bridge chip according to the seventh modification example are the same as those of the bridge chip 30 shown in FIGS. 2, 3, and 4. The bridge chip according to the seventh modification example differs from the bridge chip 30 in that the substrate 31 is made of glass.

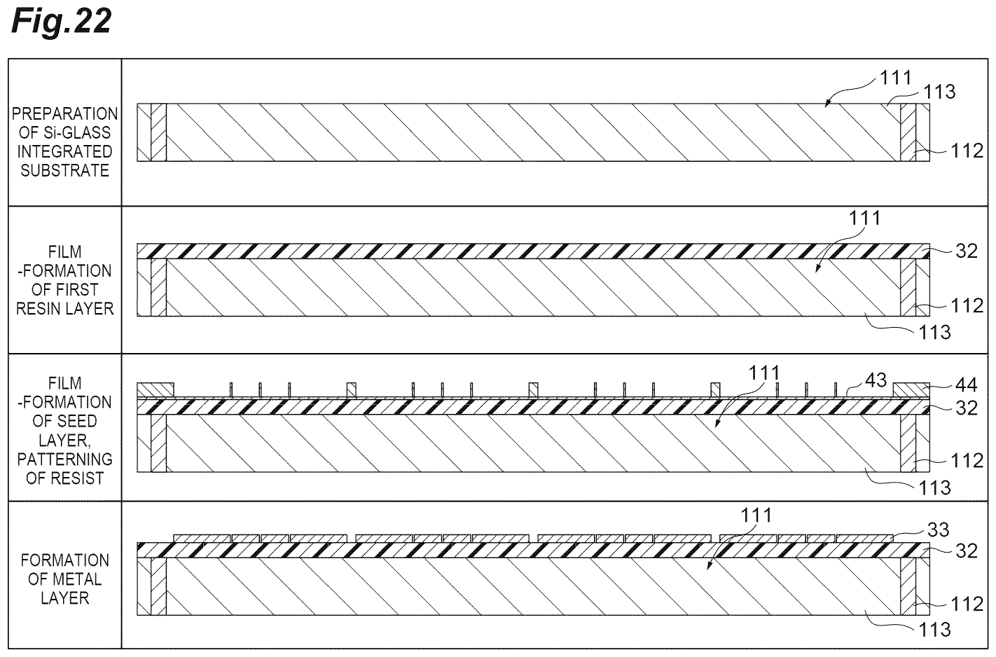

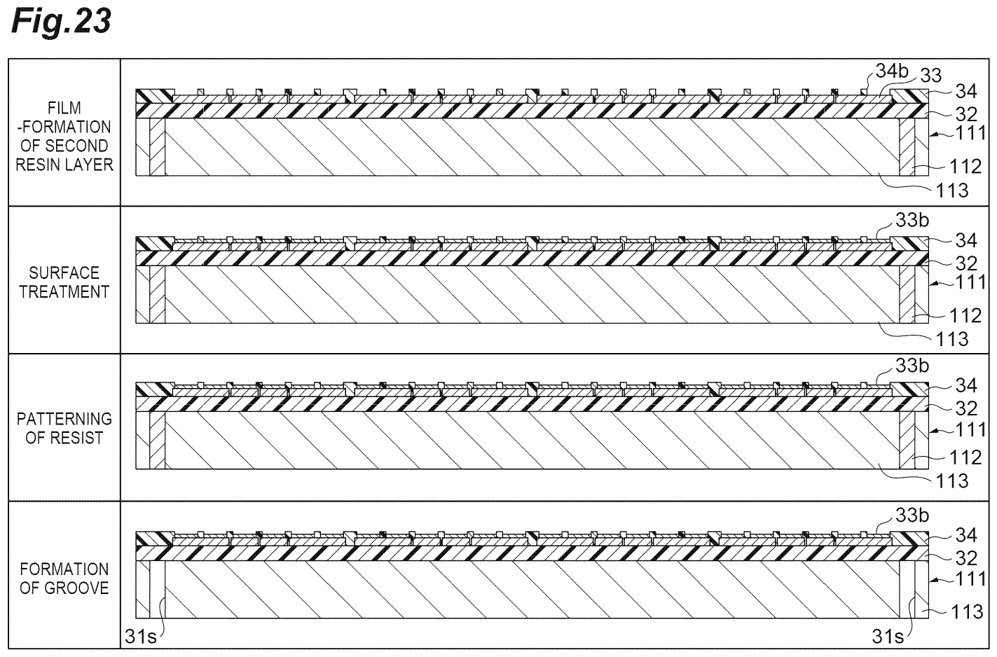

A method for manufacturing the bridge chip according to the seventh modification example will be described with reference to FIGS. 22 and 23. Hereinafter, descriptions that overlap with the method for manufacturing the bridge chip 30 shown in FIGS. 7 and 8 will be omitted as appropriate. First, a Si-glass integrated substrate 111 is prepared (a step of preparing a Si-glass integrated substrate). In the Si-glass integrated substrate 111, a portion where the groove 31s is to be formed is made of silicon 112 in advance, and a portion where the groove 31s is not to be formed is made of glass 113.

The film-formation of the first resin film 32, the film-formation of the seed layer 43, the patterning of the resist 44, the formation of the metal film 33, the film-formation of the second resin film 34, and the surface treatment of the metal film 33 are performed. After a portion of the metal film 33 exposed through the opening 34b of the second resin film 34 is subjected to the surface treatment, Si etching (for example, dry etching of the silicon 112) is performed to form the groove 31s. Then, after dicing is performed, the bridge chip according to the seventh modification example is completed. As described above, in the bridge chip according to the seventh modification example, since the substrate 31 is made of glass, thermal insulation of the substrate 31 can be further improved, and thermal crosstalk can be reduced. Further, even in the case of the bridge chip made of the glass 113 that is difficult to etch, the groove 31s can be easily manufactured by using the Si-glass integrated substrate 111 as described above. When Si is etched in FIG. 23, a resist is not used since the etching rate of glass is smaller than that of Si. However, Si may be etched using the resist 45 in the same manner as in FIG. 8.

Next, a bridge chip according to an eighth modification example will be described. The shape and size of the bridge chip according to the eighth modification example are the same as those of the bridge chip 30 shown in FIGS. 2, 3, and 4. In the bridge chip according to the eighth modification example, the support portion 31f of the substrate 31 is made of silicon, and portions of the substrate 31 other than the support portion 31f are made of glass.

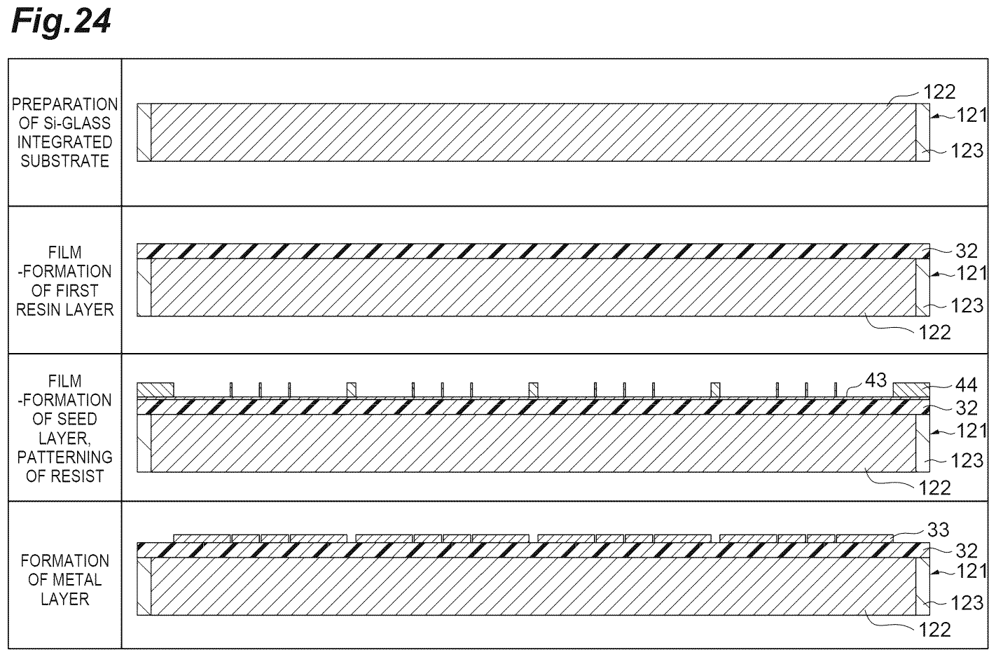

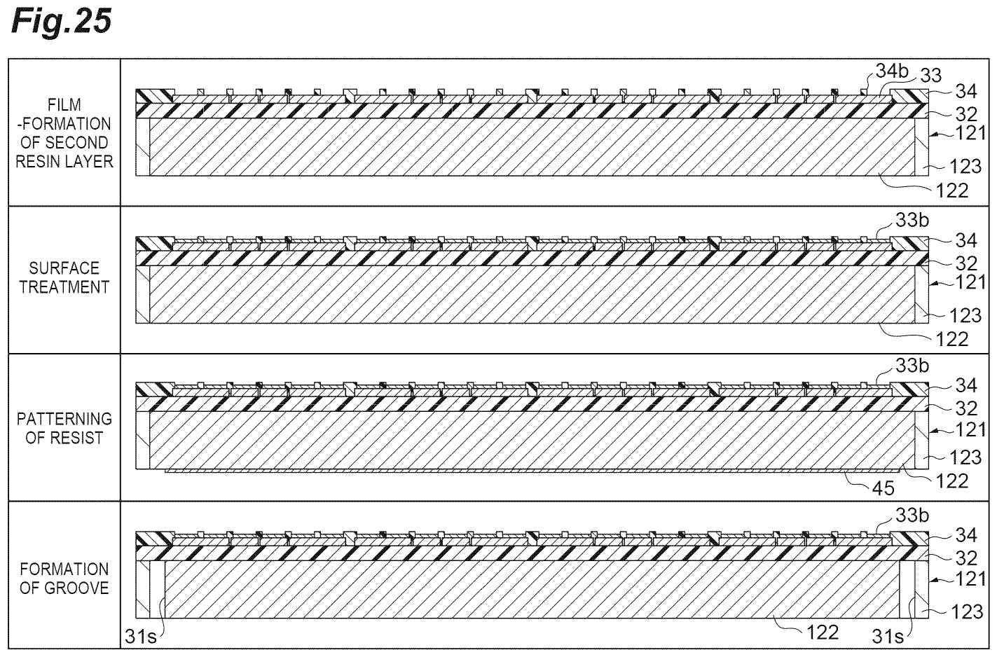

A method for manufacturing the bridge chip according to the eighth modification example will be described with reference to FIGS. 24 and 25. First, a Si-glass integrated substrate 121 is prepared (a step of preparing a Si-glass integrated substrate). In the Si-glass integrated substrate 121, portions where the groove 31s and the support portion 31f are to be formed are made of silicon 122 in advance, and portions where both the groove 31s and the support portion 31f are not to be formed are made of glass 123. Similarly to the seventh modification example described above, the film-formation of the first resin film 32, the film-formation of the seed layer 43, the patterning of the resist 44, the formation of the metal film 33, the film-formation of the second resin film 34, and the surface treatment of the metal film 33 are performed.

After a portion of the metal film 33 exposed through the opening 34b of the second resin film 34 is subjected to the surface treatment, the resist 45 is patterned on a portion of the silicon 112 where the support portion 31f is to be formed. After the resist 45 is patterned, the groove 31s is formed by performing Si etching. A portion of the silicon 122 where Si etching is not performed is formed as the support portion 31f. Then, after the resist 45 is removed and dicing is performed, the bridge chip according to the eighth modification example is completed. As described above, in the bridge chip according to the eighth modification example, a portion of the substrate 31 between the first buffer portion 31h and the second buffer portion 31j is made of glass. Therefore, in the bridge chip according to the eighth modification example, thermal insulation of the substrate 31 can be further improved, and the same effects as those of the seventh modification example can be obtained. When Si is etched in FIG. 25, the resist 45 is not formed on the glass since the etching rate of glass is smaller than that of Si. However, the resist 45 may also be formed on the glass.

The embodiment and various modification examples of the bridge chip and the semiconductor integrated module according to the present disclosure have been described above. However, the present invention is not limited to the embodiment or the various modification examples described above, and can be changed as appropriate within the scope of the concept described in the claims. In addition, the bridge chip and the semiconductor integrated module according to the present disclosure may be a combination of a plurality of examples from the embodiment and the first to eighth modification examples described above. For example, the configuration, shape, size, material, number, and disposition mode of each portion of the bridge chip and the semiconductor integrated module according to the present disclosure are not limited to the embodiment or the modification examples described above, and can be modified as appropriate. For example, in the above-described embodiment, the bridge chip 30 including the second resin film 34 has been described. However, the bridge chip may not include the second resin film 34.

What is claimed is:

1. Abridge chip comprising:
a substrate having a first surface and a second surface opposite to the first surface;
a first resin film having flexibility, and formed on the first surface of the substrate; and
a metal film formed on the first resin film,
wherein the metal film includes a connecting portion for an electrical connection with an element,
the substrate includes a buffer portion penetrating through the substrate between the first surface and the second surface, and
the connecting portion is disposed inside the buffer portion in a plan view of the substrate.

2. The bridge chip according to claim 1, further comprising:
a second resin film having flexibility, formed on the first resin film and the metal film, and having an opening on the metal film.

3. The bridge chip according to claim 1,
wherein the substrate further includes a support portion inside the buffer portion in a plan view of the substrate, and
the connecting portion is connected to the second surface of the substrate via the first resin film and the support portion.

4. The bridge chip according to claim 1, further comprising:
a solder bump formed on the connecting portion.

5. The bridge chip according to claim 1,
wherein the first resin film is made of polyimide.

6. The bridge chip according to claim 1,
wherein the metal film is made of any of copper, gold, and aluminum.

7. The bridge chip according to claim 1,
wherein the metal film includes a wiring that includes a first pad formed as the connecting portion at a first end portion, and a second pad formed as the connecting portion at a second end portion,
the first pad is configured to be electrically connectable to a first element, and
the second pad is configured to be electrically connectable to a second element isolated from the first element.

8. The bridge chip according to claim 1,
wherein the metal film includes a plurality of wirings, each extending in a first direction,
each of the plurality of wirings includes a first pad at a first end portion and a second pad at a second end portion,
the first pads of the plurality of wirings are disposed along a second direction intersecting the first direction,
the second pads of the plurality of wirings are disposed along the second direction, and
the buffer portion includes a first buffer portion including a plurality of the first pads inside the first buffer portion in a plan view of the substrate, and a second buffer portion including a plurality of the second pads inside the second buffer portion in a plan view of the substrate.

9. The bridge chip according to claim 1,
wherein the substrate is made of silicon.

10. The bridge chip according to claim 1,
wherein the substrate is made of glass.

11. The bridge chip according to claim 3,
wherein the support portion of the substrate is made of silicon.

12. A semiconductor integrated module comprising:
a base having a reference surface;
a first element that is mounted on the reference surface, and that transmits an electrical signal;
a second element that is mounted on the reference surface, and that receives the electrical signal; and
the bridge chip according to claim 1 that is connected to the first element and the second element, and that transmits the electrical signal.
